(19) United States
(12) Patent Application Publication
(10) Pub. No.: US 2026/0113890 A1
(43) Pub. Date: Apr. 23, 2026

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Kazuhiko Tsuchiya, Kakegawa-shi (JP)

(21) Appl. No.: 19/342,739

(22) Filed: Sep. 29, 2025

(30) Foreign Application Priority Data
Oct. 1, 2024 (JP) 2024-172538

(51) Int. Cl. H05K 7/20; H01R 25/16

(52) U.S. Cl. CPC H05K 7/20454; H01R 25/161; H05K 7/20481; H05K 7/20509; H05K 7/20518

(57) ABSTRACT

An electrical connection unit includes a first electronic component, a connection target component, a third electronic component, a first bus bar, a second bus bar, a heat dissipation member, a first heat transfer member, and a second heat transfer member. The first electronic component has a first terminal and a second terminal. The third electronic component has a greater amount of heat generation than the connection target component. the first bus bar electrically connects the first terminal of the first electronic component and the connection target component. the second bus bar electrically connects the second terminal of the first electronic component and the third electronic component. The heat dissipation member faces the first bus bar and the second bus bar. The first heat transfer member is disposed between the first bus bar and the heat dissipation member. The second heat transfer member is disposed between the second bus bar and the heat dissipation member, and is larger than the first heat transfer member.

### TECHNICAL FIELD

Embodiments of the present invention relate to an electrical connection unit.

Priority is claimed on Japanese Patent Application No. 2024-172538 filed in Japan on Oct. 1, 2024, the content of which is incorporated herein by reference.

### BACKGROUND ART

An electrical connection unit having an electronic component and a bus bar connected to the electronic component is known.

### PRIOR ART DOCUMENT

### Patent Document

[Patent Document 1] Japanese Unexamined Patent Application, First Publication No. 2024-037492

### SUMMARY OF THE INVENTION

### Problems to Be Solved by the Invention

Incidentally, it is expected to improve a heat dissipation property of an electrical connection unit.

An embodiment provides an electrical connection unit capable of improving a heat dissipation property.

### Means for Solving the Problem

An electrical connection unit according to an embodiment includes a first electronic component, a connection target component, a third electronic component, a first bus bar, a second bus bar, a heat dissipation member, a first heat transfer member, and a second heat transfer member. The first electronic component has a first terminal and a second terminal. The connection target component is a second electronic component or a connection component for external connection. The third electronic component has a greater amount of heat generation than the connection target component. The first bus bar electrically connects the first terminal of the first electronic component to the connection target component. The second bus bar electrically connects the second terminal of the first electronic component to the third electronic component. The heat dissipation member faces the first bus bar and the second bus bar. The first heat transfer member is disposed between the first bus bar and the heat dissipation member. The second heat transfer member is disposed between the second bus bar and the heat dissipation member, and is larger than the first heat transfer member.

### Effects of Invention

According to one embodiment, it is possible to improve a heat dissipation property.

### BRIEF DESCRIPTION OF THE DRAWINGS

FIG. 1 A cross-sectional view illustrating an electrical connection unit of a first embodiment.

FIG. 2 A perspective view for describing a main body of the first embodiment.

FIG. 3 A perspective view for describing a subunit of the first embodiment.

FIG. 4 A partially exploded perspective view of the subunit of the first embodiment.

FIG. 5 A perspective view for describing an electronic component and a connection component of the first embodiment.

FIG. 6 A perspective view for describing the electronic component and the connection component of the first embodiment.

FIG. 7 A perspective view illustrating the connection component of the first embodiment.

FIG. 8 A perspective view illustrating a routing board of the first embodiment.

FIG. 9 A partially exploded perspective view of the routing board of the first embodiment.

FIG. 10 A plan view illustrating the routing board of the first embodiment.

FIG. 11 A partially exploded perspective view of the electrical connection unit of the first embodiment.

FIG. 12 A bottom view illustrating the routing board of the first embodiment.

FIG. 13 A cross-sectional view taken along line F13-F13 of a structure illustrated in FIG. 10.

FIG. 14 A cross-sectional view illustrating a modification example of the first embodiment.

FIG. 15 A cross-sectional view illustrating a modification example of the first embodiment.

FIG. 16 A cross-sectional view illustrating a modification example of the first embodiment.

FIG. 17 A cross-sectional view illustrating a modification example of the first embodiment.

FIG. 18 A plan view for describing a size and a disposition of the heat transfer member of the first embodiment.

FIG. 19 A bottom view for describing a size and a disposition of the heat transfer member of the first embodiment.

FIG. 20 A cross-sectional view taken along line F20-F20 of the structure illustrated in FIG. 10.

FIG. 21 A plan view illustrating an electrical connection unit of a second embodiment.

FIG. 22 A cross-sectional view taken along line F22-F22 of the electrical connection unit illustrated in FIG. 21.

### EMBODIMENTS FOR CARRYING OUT THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

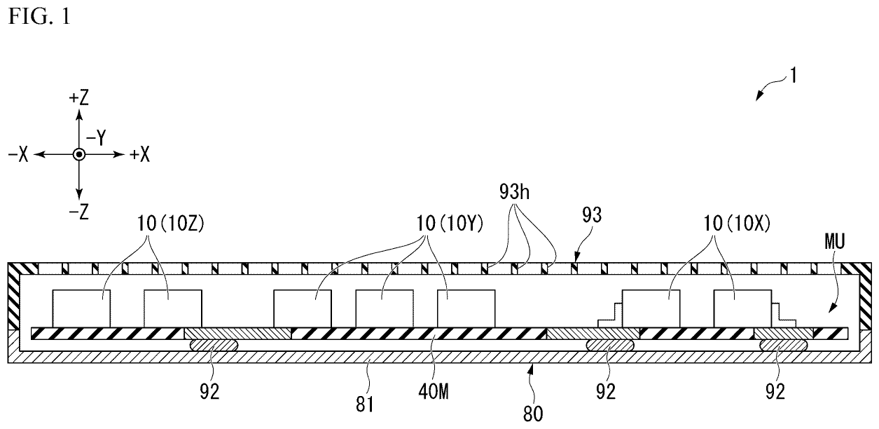

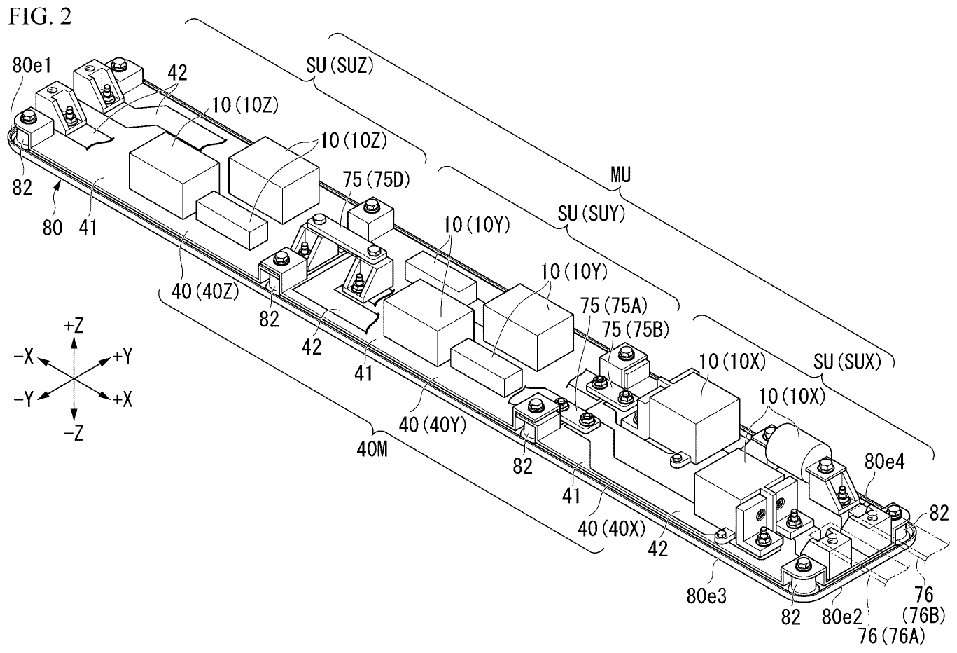

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 2). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 2). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “first direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### FIRST EMBODIMENT

### 1. Constitution of Electrical Connection Unit

FIG. 1 is a cross-sectional view illustrating an electrical connection unit 1 of an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

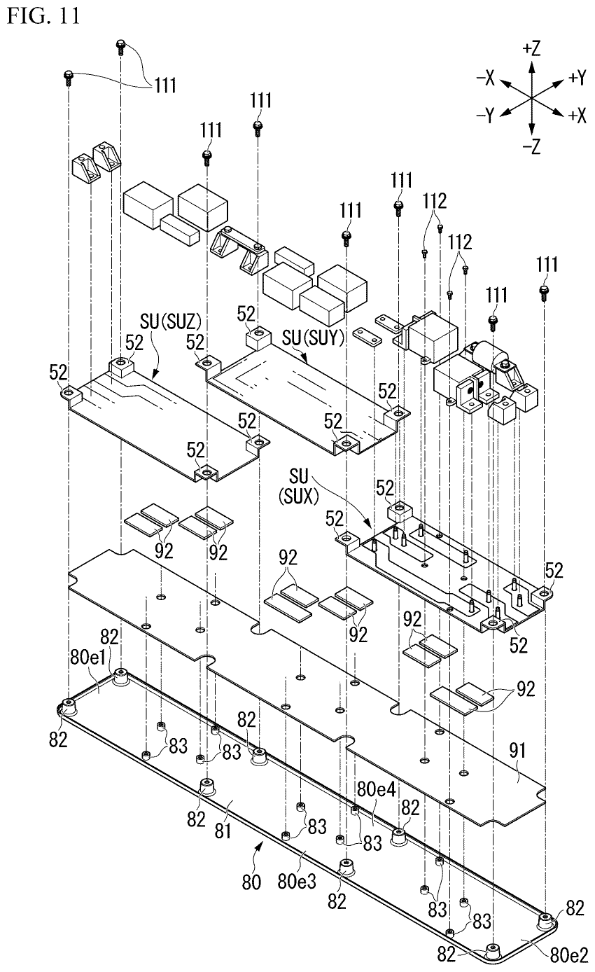

The electrical connection unit 1 includes, for example, a main body MU, a metal plate 80, an insulating sheet 91 (see FIG. 11), a plurality of heat transfer members 92, and an insulating cover 93.

### 2. Main Body

First, the main body MU will be described.

FIG. 2 is a perspective view for describing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting a plurality of subunits SU. In the present embodiment, the main body MU includes three subunits SU (subunits SUX, SUY, and SUZ). Each subunit SU may be referred to as a “circuit constitution body”.

The subunit SUX has an electrical first function. The subunit SUX includes, for example, a plurality of electronic components 10X and a first routing board 40X. The plurality of electronic components 10X are electrically connected to the first routing board 40X.

The subunit SUY has an electrical second function. The second function is a function different from the first function. The subunit SUY includes, for example, a plurality of electronic components 10Y and a second routing board 40Y. The plurality of electronic components 10Y are electrically connected to the second routing board 40Y.

The subunit SUZ has an electrical third function. The third function is a function different from the first function and the second function. The subunit SUZ includes, for example, a plurality of electronic components 10Z and a third routing board 40Z. The plurality of electronic components 10Z are electrically connected to the third routing board 40Z.

In the present embodiment, the three subunits SUX, SUY, and SUZ are disposed to be arranged in the X direction. For example, the subunit SUX is disposed on the +X direction side with respect to the subunit SUY. The subunit SUX and the subunit SUY are electrically connected via a plurality of coupling bus bars 75 extending between the first routing board 40X and the second routing board 40Y. On the other hand, the subunit SUZ is disposed on the −X direction side with respect to the subunit SUY. The subunit SUZ and the subunit SUY are electrically connected via a plurality of coupling bus bars 75 (only one is illustrated in FIG. 2) extending between the third routing board 40Z and the second routing board 40Y. The coupling bus bar 75 is disposed on the side opposite to the metal plate 80 with respect to the plurality of subunits SU.

In the present embodiment, the three routing boards 40X, 40Y, and 40Z included in the three subunits SUX, SUY, and SUZ are disposed on the same plane. In other words, the three routing boards 40X, 40Y, and 40Z are disposed at the same height position in the Z direction. As a result, one large routing board 40M is formed by the three routing boards 40X, 40Y, and 40Z.

In the present embodiment, the three subunits SUX, SUY, and SUZ have the same or similar basic structure. Therefore, one subunit SU will be described in detail below as a representative. Hereinafter, in a case where the subunit SUX, the subunit SUY, and the subunit SUZ are not distinguished, the subunits are simply referred to as “subunit SU”. In addition, in a case where the electronic component 10X, the electronic component 10Y, and the electronic component 10Z are not distinguished, the electronic components are simply referred to as “electronic component 10”. In a case where the first routing board 40X, the second routing board 40Y, and the third routing board 40Z are not distinguished, the routing boards are simply referred to as “routing board 40”. One subunit SU included in the three subunits SUX, SUY, and SUZ is an example of a “first subunit”. On the other hand, another subunit SU included in the three subunits SUX, SUY, and SUZ is an example of a “second subunit”.

Note that the main body MU need not be divided into a plurality of subunits SU instead of the example described above. That is, the main body MU may be formed by the plurality of electronic components 10 and one routing board 40. In addition, the two or more subunits SU are not limited to the subunits SU having different functions, and may be the subunits SU having the same function.

### 3. Constitution of Subunit

Next, a constitution of the subunit SU will be described.

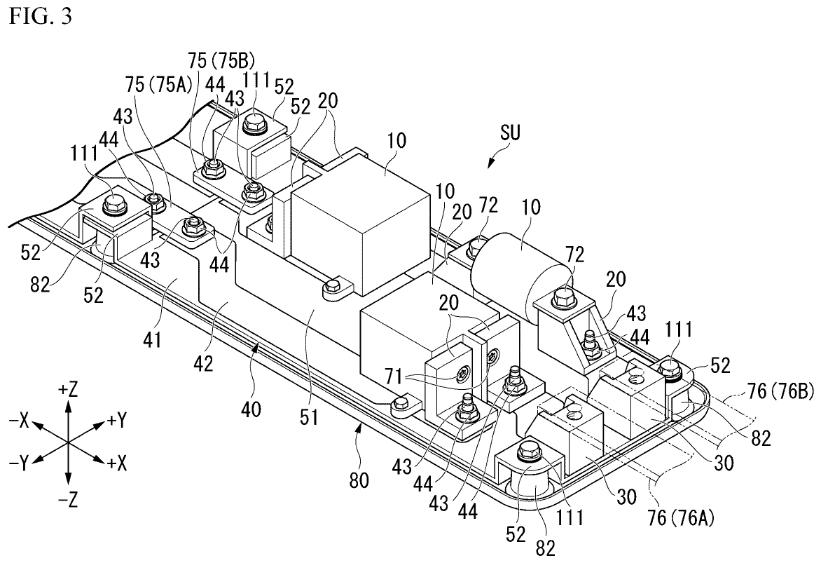

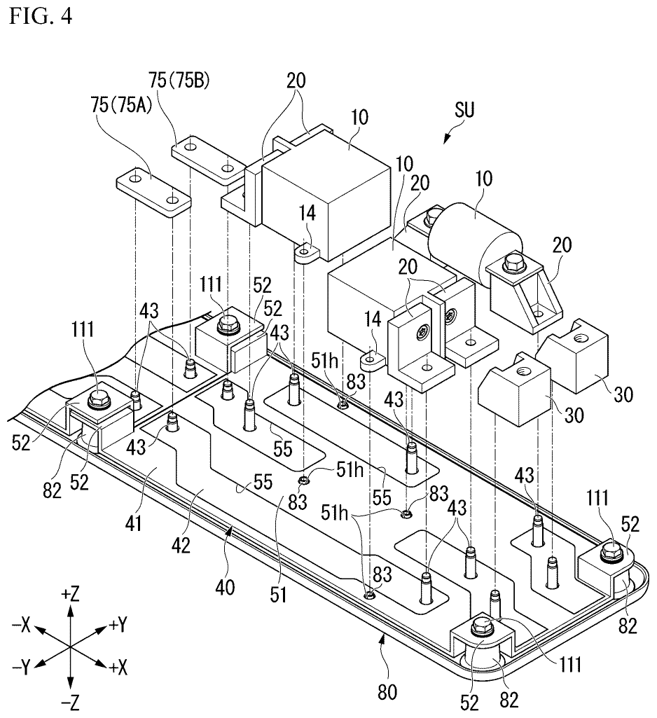

FIG. 3 is a perspective view for describing the subunit SU. FIG. 4 is a partially exploded perspective view of the subunit SU. The subunit SU includes, for example, a plurality of electronic components 10, a plurality of connection components 20 for component connection, a plurality of connection components 30 for external connection, and a routing board 40. The connection components 20 and 30 are members forming an energization path in the vertical direction. The connection components 20 and 30 may be referred to as “vertical routing members”.

### 3.1 Electronic Component and Connection Component for Component Connection

First, the electronic component 10 and the connection component 20 for component connection will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization. Hereinafter, a first-type electronic component 10M and a second-type electronic component 10N will be described as examples of the electronic component 10.

The connection component 20 is a component that electrically connects the electronic component 10 to the routing board 40. The connection component 20 forms a part of an energization path in the subunit SU. The connection component 20 is made of a metal (for example, copper or a copper alloy). The connection component 20 may be referred to as a “metal component”. Hereinafter, a first-type connection component 20M and a second-type connection component 20N will be described as examples of the connection component 20.

### 3.1.1 First-Type Electronic Component

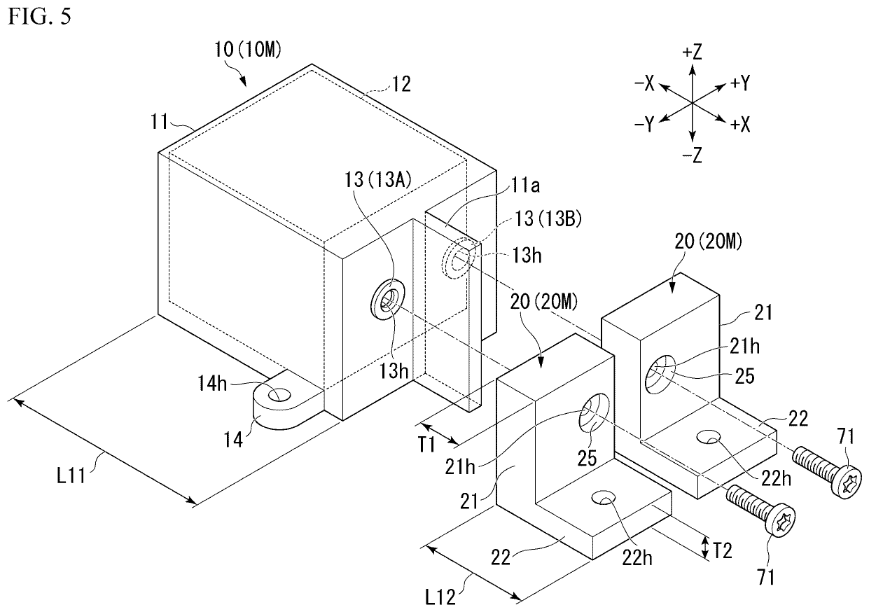

FIG. 5 is a perspective view illustrating the first-type electronic component 10M and the first-type connection component 20M. The first-type electronic component 10M is an electronic component in which a plurality of terminals 13 are disposed to be arranged at one end of the electronic component 10M. The electronic component 10M includes, for example, a case 11, a component body 12, a plurality of terminals 13, and a plurality of attachment portions 14.

### Case

The case 11 is an outer member that forms most of the outer shape of the electronic component 10M. The case 11 is made of, for example, synthetic resin and has an insulating property. The case 11 accommodates the component body 12. The case 11 and the component body 12 may be integrally formed.

In the present embodiment, the case 11 has an insulating rib 11a that protrudes in the horizontal direction (for example, the X direction) and extends in the Z direction. The insulating rib 11a has, for example, a plate shape formed in the horizontal direction (for example, the X direction) and the Z direction. The insulating rib 11a extends over the entire length of the case 11 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, a part of the insulating rib 11a is disposed between first portions 21 (that will be described later) of two connection components 20M connected to the electronic component 10M. The insulating rib 11a electrically insulates the first portions 21 of the two connection components 20M connected to the electronic component 10M from each other.

### Component Body

The component body 12 is a portion that performs a main function of the electronic component 10M. For example, in a case where the electronic component 10M is a relay, the component body 12 includes a switch (for example, a contact) that switches between a conductive state and a non-conductive state. For example, in a case where the electronic component 10M is a fuse, the component body 12 includes a fusion portion that is fused when an overcurrent flows. For example, in a case where the electronic component 10M is a capacitor, the component body 12 includes a portion that stores electric charge.

### Terminal

The terminal 13 is an electrical connection portion exposed to the outside of the case 11. The terminal 13 is electrically connected to the component body 12 inside the case 11. In the present embodiment, the electronic component 10M includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side. One of the terminal 13A and the terminal 13B is an example of a “first terminal”. The other of the terminal 13A and the terminal 13B is an example of a “second terminal”.

In the present embodiment, the terminal 13A and the terminal 13B are provided at one end of the electronic component 10M in the horizontal direction (for example, the X direction). The terminal 13A and the terminal 13B are disposed to be arranged in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the X direction). An inner circumferential surface of the attachment hole 13h of the electronic component 10M has a screw groove.

### Attachment Portion

The attachment portion 14 is a portion for fixing the electronic component 10M. The attachment portion 14 has an attachment hole 14h to which a fastening member 112 (for example, a screw or a bolt; and see FIG. 11) that will be described later is attached. The attachment hole 14h is open in the Z direction. The attachment hole 14h is an insertion hole through which the fastening member 112 passes. A fixing destination of the attachment portion 14 will be described later.

### 3.1.2 First-Type Connection Component

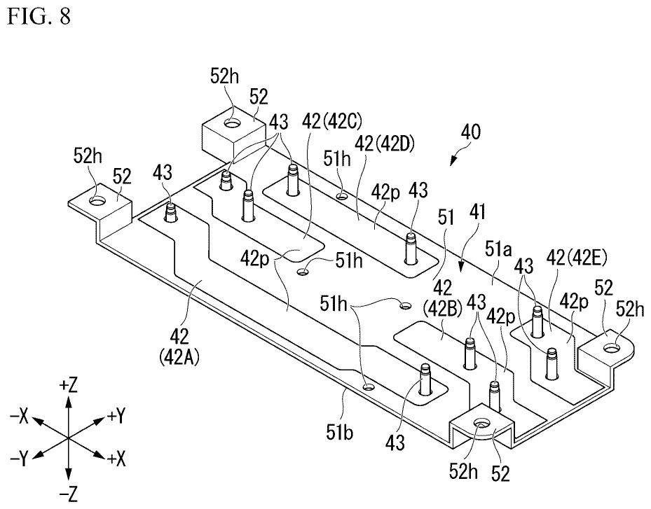

The first-type connection component 20M is a component that electrically connects the first-type electronic component 10M to the routing board 40. In the present embodiment, the connection component 20M electrically connects the electronic component 10M to a bus bar 42 (see FIG. 8) included in the routing board 40. In the present embodiment, a width L12 of the connection component 20M in a longitudinal direction (for example, the X direction) of the electronic component 10M is smaller than a width L11 of the electronic component 10M in the longitudinal direction. The connection component 20M includes, for example, a first portion 21 and a second portion 22.

### First Portion

The first portion 21 of the connection component 20M is a portion connected to the terminal 13 of the electronic component 10M. The first portion 21 is a plate-shaped or rectangular parallelepiped portion extending in the Z direction. The first portion 21 extends in the Z direction along one end (for example, an end in the X direction) of the electronic component 10M. The first portion 21 is a standing portion that stands in the Z direction with respect to the routing board 40 (for example, with respect to a bus bar 42 that will be described later). The first portion 21 is adjacent to the electronic component 10M in the horizontal direction (for example, the X direction). For example, the first portion 21 is adjacent to the terminal 13 of the electronic component 10M in the horizontal direction (for example, the X direction), and is connected to the terminal 13 of the electronic component 10M from the horizontal direction (for example, the X direction).

The first portion 21 of the connection component 20M has a first attachment hole 21h through which the fastening member 71 (for example, a screw or a bolt) passes. The first attachment hole 21h is open in the horizontal direction (for example, the X direction). The first portion 21 has a recess 25 around the first attachment hole 21h. The recess 25 is an accommodation portion that accommodates a head of the fastening member 71 inserted into the first attachment hole 21h. The fastening member 71 that has passed through the first attachment hole 21h is engaged with the attachment hole 13h of the terminal 13 of the electronic component 10M, and thus the first portion 21 is physically and electrically connected to the terminal 13 of the electronic component 10M. The first portion 21 need not have the recess 25.

### Second Portion

The second portion 22 of the connection component 20M is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20M is attached to the fastening member 43 (for example, a screw or a bolt; and see FIG. 8) protruding from the bus bar 42 in the +Z direction from the Z direction, and is physically and electrically connected to the bus bar 42. In the present embodiment, the second portion 22 of the connection component 20M has a second attachment hole 22h through which the fastening member 43 passes. The second attachment hole 22h is open in the Z direction. In the second portion 22, the fastening member 43 passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42. In the present embodiment, the first portion 21 and the second portion 22 form one L-shaped connection component 20M.

### 3.1.3 Second-Type Electronic Component

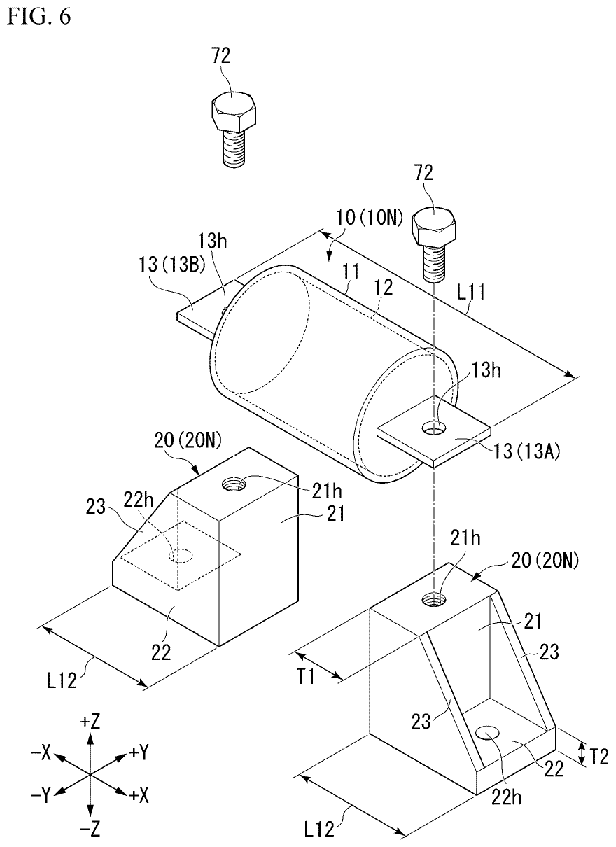

FIG. 6 is a perspective view illustrating the second-type electronic component 10N and the second-type connection component 20N. The second-type electronic component 10N is an electronic component in which two terminals 13 are separately disposed at both ends in the horizontal direction of the electronic component 10N. The electronic component 10N includes, for example, a case 11, a component body 12, and a plurality of terminals 13. Note that, among the constitutions of the electronic component 10N, constitutions having functions similar to those of the electronic component 10M are denoted by the same reference numbers. In this case, in the description regarding the electronic component 10N, the “electronic component 10M” may be replaced with the “electronic component 10N” in the description regarding the electronic component 10M described above.

In the electronic component 10N, the terminal 13A and the terminal 13B are disposed separately at both ends of the electronic component 10N in the horizontal direction (for example, the X direction). Each terminal 13 has an attachment hole 13h to which a fastening member 72 (for example, a screw or a bolt) that will be described later is attached. The attachment hole 13h is open in the Z direction. For example, the attachment hole 13h of the electronic component 10N is an insertion hole through which the fastening member 72 passes. One of the terminal 13A and the terminal 13B is an example of a “first terminal”. The other of the terminal 13A and the terminal 13B is an example of a “second terminal”.

### 3.1.4 Second-Type Connection Component

The second-type connection component 20N is a component that electrically connects the second-type electronic component 10N to the routing board 40. In the present embodiment, the connection component 20N electrically connects the electronic component 10N to the bus bar 42 (see FIG. 8) included in the routing board 40. In the present embodiment, a width L12 of the connection component 20N in the longitudinal direction (for example, the X direction) of the electronic component 10N is smaller than a width L11 of the electronic component 10N in the longitudinal direction. The connection component 20N includes, for example, a first portion 21, a second portion 22, and a third portion 23.

### First Portion

The first portion 21 of the connection component 20N is a portion connected to the terminal 13 of the electronic component 10N. The first portion 21 is a rectangular parallelepiped portion extending in the Z direction. The first portion 21 is a standing portion that stands in the Z direction with respect to the routing board 40 (for example, with respect to the bus bar 42). The first portion 21 is adjacent to the terminal 13 of the electronic component 10N in the Z direction, and is connected to the terminal 13 of the electronic component 10N from the Z direction. The first portion 21 of the connection component 20N has a first attachment hole 21h with which the fastening member 72 is engaged. The first attachment hole 21h is open in the Z direction. An inner circumferential surface of the first attachment hole 21h of the connection component 20N has a screw groove. The fastening member 72 that has passed through the attachment hole 13h of the terminal 13 of the electronic component 10N is engaged with the attachment hole 21h of the first portion 21, and thus the first portion 21 is physically and electrically connected to the terminal 13 of the electronic component 10N.

### Second Portion

The second portion 22 of the connection component 20N is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20N is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 22 of the connection component 20N has a second attachment hole 22h through which the fastening member 43 passes. The second attachment hole 22h is open in the Z direction. In the second portion 22, the fastening member 43 that will be described later passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42.

### Third Portion

The third portion 23 is a standing wall (side wall) standing in the +Z direction from both ends of the second portion 22 in the horizontal direction. The third portion 23 is a wall provided in the Z direction. The third portion 23 is connected to the first portion 21 and is also connected to the second portion 22. For example, the third portion 23 extends obliquely so as to increase in the X direction as it advances in the −Z direction. The third portion 23 may be provided in the connection component 20M described above. On the other hand, the connection component 20N need not have the third portion 23.

### 3.1.5 Structure Related to Connection Component

In the present embodiment, the connection components 20 (for example, the connection component 20M and the connection component 20N) are heat storage members (heat absorbing members) that increase the heat capacity of the energization path of the electrical connection unit 1. The connection component 20 stores (absorbs) at least a part of heat generated by the electronic component 10, for example. Alternatively/additionally, the connection component 20 may store (absorb) at least a part of heat generated by the bus bar 42 itself due to energization. The connection component 20 may be referred to as a “heat storage component”or a “heat absorbing component”.

In the present embodiment, the bus bar 42 is disposed at a position away from the terminal 13 of the electronic component 10 (for example, a position away in the Z direction). The connection component 20 is disposed between the electronic component 10 and the bus bar 42. In the present disclosure, the phrase “the connection component is disposed between the electronic component and the bus bar” is not limited to a case where a part of the connection component is located between the electronic component and the bus bar when viewed from the X direction or the Y direction. The phrase “the connection component is disposed between the electronic component and the bus bar” may correspond to a case where a part of the connection component is located between the electronic component and the bus bar when viewed from a direction inclined with respect to the X direction or the Y direction. The connection component 20 electrically connects the terminal 13 of the electronic component 10 to the bus bar 42.

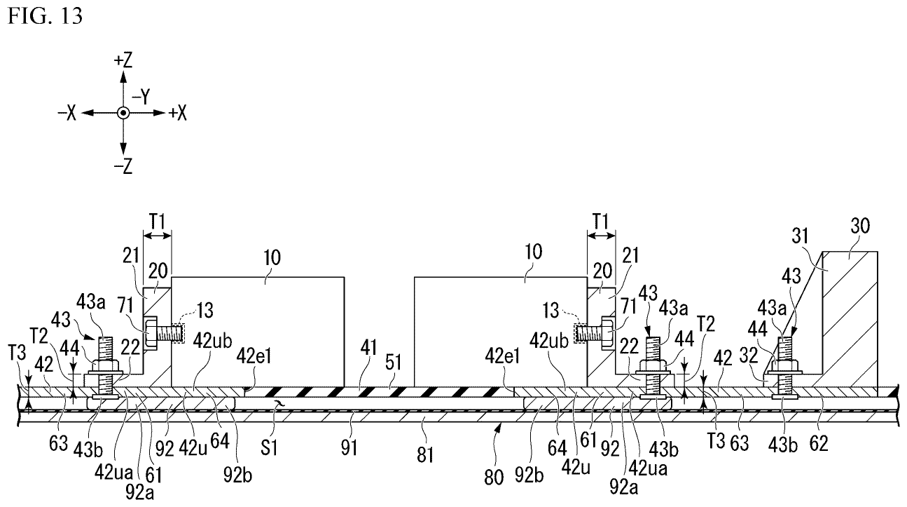

In the present embodiment, the thickness of at least a part of the connection component 20 is larger than a plate thickness (thickness in the Z direction) T3 of the bus bar 42 (see FIG. 13). For example, a thickness T1 of at least a part of the connection component 20 in the X direction is larger than the plate thickness T3 of the bus bar 42. In the present embodiment, the thickness T1 of the first portion 21 of the connection component 20 in the X direction is larger than the plate thickness T3 of the bus bar 42. In the present embodiment, the first portion 21 has the thickness T1 larger than the plate thickness T3 of the bus bar 42 as a thickness in the X direction over the entire length of the first portion 21 in the Z direction. The thickness T1 of the first portion 21 of the connection component 20 in the X direction is, for example, twice or more the plate thickness T3 of the bus bar 42. From another point of view, a thickness T2 of the second portion 22 of the connection component 20 in the Z direction may be larger than the plate thickness T3 of the bus bar 42.

In the present embodiment, the thickness T1 of the first portion 21 of the connection component 20 in the X direction is larger than the thickness T2 of the second portion 22 of the connection component 20 in the Z direction. In the present embodiment, the first portion 21 has the thickness T1 larger than the thickness T2 of the second portion 22 in the Z direction as a thickness in the X direction over the entire length of the first portion 21 in the Z direction.

### 3.2 Connection Component for External Connection

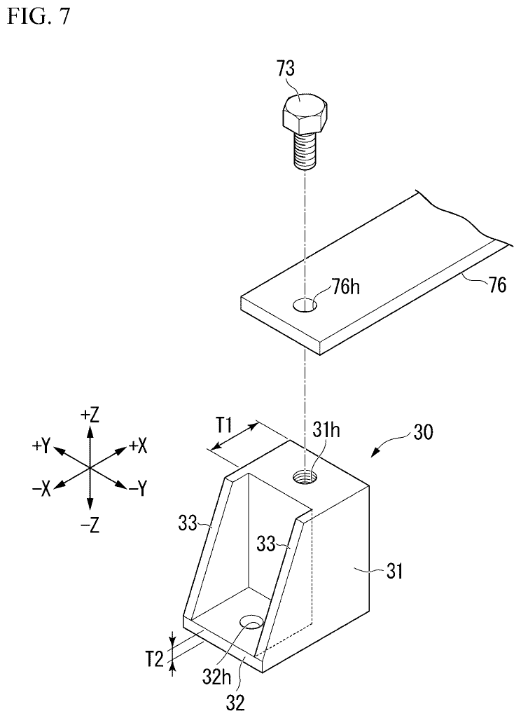

Next, the connection component 30 for external connection will be described. FIG. 7 is a perspective view illustrating the connection component 30 for external connection. The connection component 30 is a component that electrically connects an external coupling bus bar 76 to the routing board 40. In the present embodiment, the connection component 30 electrically connects the external connection bus bar 76 to the bus bar 42 (see FIG. 8) included in the routing board 40. The external connection bus bar 76 is electrically connected to an external device. In the present disclosure, the “external device” is an electrical device existing outside the electrical connection unit 1. The external device is, for example, a battery unit mounted on a vehicle or an inverter for driving a motor of the vehicle, but is not limited to these examples. The connection component 30 includes, for example, a first portion 31, a second portion 32, and a third portion 33.

### First Portion

The first portion 31 is a portion connected to the external connection bus bar 76. The first portion 31 is a rectangular parallelepiped portion extending in the Z direction. The first portion 31 is a standing portion standing in the Z direction with respect to the routing board 40 (for example, with respect to the bus bar 42). The first portion 31 is adjacent to the external connection bus bar 76 in the Z direction, and is connected to the external connection bus bar 76 from the Z direction. The first portion 31 has a first attachment hole 31h through which a fastening member 73 (for example, a screw or a bolt) passes. The first attachment hole 31h is open in the Z direction. An inner circumferential surface of the first attachment hole 31h has a screw groove. The fastening member 73 that has passed through the attachment hole 76h of the external connection bus bar 76 is engaged with the attachment hole 31h of the first portion 31, and thus the first portion 31 is physically and electrically connected to the external connection bus bar 76.

### Second Portion

The second portion 32 is a portion connected to the bus bar 42 (see FIG. 8). The second portion 32 protrudes in the horizontal direction (for example, the X direction) from the end of the first portion 31 on the −Z direction side. The second portion 32 is a plate portion provided in the horizontal direction. The second portion 32 is adjacent to the bus bar 42 in the Z direction, and is connected to the bus bar 42 from the Z direction. The second portion 32 is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 32 has a second attachment hole 32h through which the fastening member 43 passes. The second attachment hole 32h is open in the Z direction. In the second portion 32, the fastening member 43 that will be described later passes through the second attachment hole 32h. The engagement member 44 (for example, a nut; and see FIG. 3) is engaged with the tip of the fastening member 43 that has passed through the second attachment hole 32h, and thus the second portion 32 is fixed to the bus bar 42.

### Third Portion

The third portion 33 is a standing wall (side wall) standing in the +Z direction from both ends of the second portion 32 in the horizontal direction. The third portion 33 is a wall provided in the Z direction. The third portion 33 is connected to the first portion 31 and is also connected to the second portion 32. For example, the third portion 33 extends obliquely to increase in the X direction (or the Y direction) as proceeding in the −Z direction. The connection component 30 need not include the third portion 33.

Note that the dimensional relationship (for example, a dimensional relationship related to the thicknesses T1, T2, and T3) related to the connection component 20 and the bus bar 42 described above is the same for the connection component 30 to which the external connection bus bar 76 is connected. For example, in the description of the connection component 30, the “connection component 20” may be replaced with the “connection component 30” , the “first portion 21” may be replaced with the “first portion 31”, and the “second portion 22” may be replaced with the “second portion 32” in the description of the connection component 20.

### 3.3 Routing Board

Next, the routing board 40 will be described.

FIG. 8 is a perspective view illustrating the routing board 40. The routing board 40 is a member that forms at least a part of an energization path between the plurality of electronic components 10 and/or at least a part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40 has a plate shape formed in the X direction and the Y direction.

The routing board 40 includes, for example, a base plate 41, one or more (for example, a plurality of) bus bars 42, and a plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board 40 may be formed by another structure instead of the insert molding. A modification example in which the routing board 40 is formed by another structure will be described later.

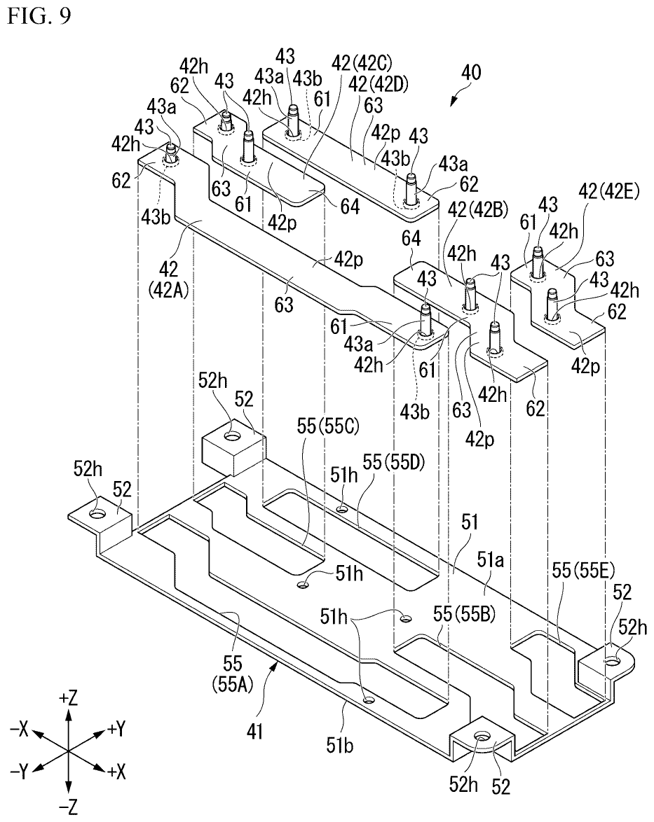

FIG. 9 is a partially exploded perspective view of the routing board 40. Hereinafter, for convenience of description, the base plate 41, the bus bar 42, and the fastening member 43 will be described with reference to the drawings in which the routing board 40 is partially exploded.

### Base Plate

The base plate 41 is a holding member that integrally holds the plurality of bus bars 42 arranged in the horizontal direction at intervals. The base plate 41 is made of, for example, synthetic resin and has an insulating property. The base plate 41 electrically insulates the plurality of bus bars 42 from each other. The base plate 41 is an example of a “base member”. The base plate 41 may be referred to as an “insulating substrate”. The base plate 41 includes, for example, a flat surface portion 51 and a plurality of fixing portions 52. The fixing portion 52 will be described later.

The flat surface portion 51 is a portion formed in a plate shape in the base plate 41. The flat surface portion 51 has a plate shape formed in the horizontal direction. The flat surface portion 51 forms a main portion of the base plate 41. The flat surface portion 51 forms a base portion (insulating base portion) of the base plate 41. In the present embodiment, the flat surface portion 51 extends over the entire width in the X direction of the base plate 41 and over the entire width in the Y direction of the base plate 41 except for four corner portions of the base plate 41.

The flat surface portion 51 has a first surface 51a and a second surface 51b. The first surface 51a is a surface directed in the +Z direction. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed in the −Z direction. The second surface 51b is a flat surface provided in the horizontal direction. The second surface 51b faces the metal plate 80 (see FIG. 1). A thickness direction (plate thickness direction) of the flat surface portion 51 is the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where a part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41). Similarly, in the present disclosure, the phrase “the accommodation portion is recessed in the first direction (Z direction)” may include a case where a part of the entire length of the accommodation portion 55 is recessed in the Z direction (for example, a remaining portion of the accommodation portion 55 may be a through-hole penetrating the flat surface portion 51 in the Z direction, or may be provided inside the base plate 41 and not exposed to the outside of the base plate 41).

Each accommodation portion 55 has an outer shape corresponding to the shape of the bus bar 42 to be accommodated when viewed from the Z direction. In the present embodiment, the flat surface portion 51 includes, for example, five accommodation portions 55A, 55B, 55C, 55D, and 55E as the plurality of accommodation portions 55. The accommodation portion 55A is provided to correspond to a bus bar 42A that will be described later, and accommodates the bus bar 42A. The accommodation portion 55B is provided to correspond to a bus bar 42B that will be described later, and accommodates the bus bar 42B. The accommodation portion 55C is provided to correspond to a bus bar 42C that will be described later, and accommodates the bus bar 42C. The accommodation portion 55D is provided to correspond to a bus bar 42D that will be described later, and accommodates the bus bar 42D. The accommodation portion 55E is provided to correspond to a bus bar 42E that will be described later, and accommodates the bus bar 42E.

At least the surface of the base plate 41 may have a color having a higher thermal emissivity than the bus bar 42. For example, at least the surface of the base plate 41 is colored black. Note that the base plate 41 having a specific color may be realized by applying the specific color to the surface of the base plate 41, or a material itself of the base plate 41 may have the specific color. When at least the surface of the base plate 41 has a color having a higher thermal emissivity than the bus bar 42, heat dissipation from the base plate 41 can be further promoted.

### Bus Bar

The bus bar 42 is a routing member (electrical connection member) included in the routing board 40. The bus bar 42 is, for example, a routing member for electrically connecting the plurality of electronic components 10. Alternatively, the bus bar 42 may be a routing member for connecting the electronic component 10 to an external device. The bus bar 42 is made of a metal (for example, copper or a copper alloy) and has conductivity. In the present embodiment, the routing board 40 includes, for example, five bus bars 42A, 42B, 42C, 42D, and 42E as the plurality of bus bars 42. The five bus bars 42A, 42B, 42C, 42D, and 42E are disposed to be arranged in the horizontal direction at intervals. The five bus bars 42A, 42B, 42C, 42D, and 42E include portions arranged on the same plane. The five bus bars 42A, 42B, 42C, 42D, and 42E are held by the flat surface portion 51 of the base plate 41.

At least a part of each bus bar 42 has a plate shape formed in the horizontal direction. At least a part of each bus bar 42 is accommodated in the accommodation portion 55 and extends along the flat surface portion 51. That is, at least a part of each bus bar 42 extends along the first surface 51a of the flat surface portion 51. At least a part of each bus bar 42 extends in the horizontal direction in the accommodation portion 55. In the present embodiment, each bus bar 42 has a plate shape formed in the horizontal direction over the entire bus bar 42. Each of the bus bars 42 is accommodated in the accommodation portion 55 over the entire length of the bus bar 42 and extends along the flat surface portion 51. Hereinafter, a portion of each bus bar 42 that is accommodated in the accommodation portion 55 and extends along the flat surface portion 51 may be referred to as a “plate portion 42p”. The bus bar 42 is a member that forms a horizontal energization path. The bus bar 42 may be referred to as a “horizontal routing member”.

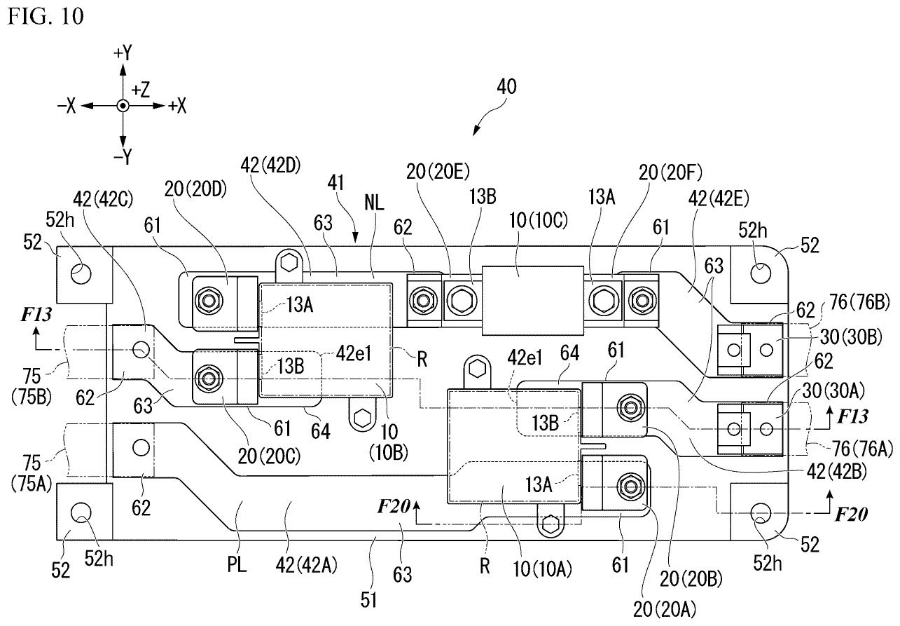

FIG. 10 is a plan view illustrating the routing board 40. The plate portion 42p of each bus bar 42 has, for example, a first connection portion 61, a second connection portion 62, and an extending portion 63.

The first connection portion 61 is a portion in contact with one connection component 20 (hereinafter referred to as a “first connection component 20”). The first connection component 20 is a connection component that connects one electronic component 10 (hereinafter referred to as a “first electronic component 10”) to the bus bar 42. The first connection portion 61 is a portion of the bus bar 42 overlapping the first connection component 20 when viewed from the Z direction. The first connection portion 61 is adjacent to the first connection component 20 in the Z direction, and is connected to the first connection component 20 from the Z direction.

The second connection portion 62 is a portion in contact with another connection component 20 (hereinafter referred to as a “second connection component 20”). The second connection component 20 is a connection component that connects another electronic component 10 (hereinafter referred to as a “second electronic component 10”) included in the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction, and is connected to the second connection component 20 from the Z direction.

Note that the second connection portion 62 may be a portion in contact with another connection component 30 (hereinafter referred to as a “second connection component 30”) instead of the above example. The connection component 30 is a connection component for connecting an external device to the bus bar 42. In this case, the second connection portion 62 is a portion of the bus bar 42 overlapping the second connection component 30 when viewed from the Z direction. The second connection portion 62 is adjacent to the second connection component 30 in the Z direction, and is connected to the second connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction, and is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 is accommodated in the accommodation portion 55 at least over the first connection portion 61 and the second connection portion 62 and extends along the flat surface portion 51. For example, the first connection portion 61, the second connection portion 62, and the extending portion 63 are accommodated in the accommodation portion 55 and extend along the flat surface portion 51.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends linearly in the X direction. The extending portion 63 extends over a region R overlapping the electronic component 10 when viewed from the Z direction, over the +X direction side and the −X direction side of the region R. That is, the bus bar 42 is accommodated in the accommodation portion 55 to be easily routed through a better path (for example, a path with a shorter distance) without being disturbed by the presence of the electronic component 10.

The one or more bus bars 42 may have an extension 64 in addition to the first connection portion 61, the second connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 is accommodated in the accommodation portion 55 and extends along the flat surface portion 51. The extension 64 extends to the region R overlapping the electronic component 10 when viewed from the Z direction, and has an end 42e1 of the bus bar 42 at a position overlapping the electronic component 10 when viewed from the Z direction.

Some routing examples of the bus bar 42 will be described below. The plurality of electronic components 10 include three electronic components 10A, 10B, and 10C. The electronic component 10A and the electronic component 10B are, for example, the first-type electronic component 10M. The electronic component 10C is, for example, the second-type electronic component 10N. Note that the type of the electronic component 10 is not limited to the above example. The plurality of connection components 20 include six connection components 20A, 20B, 20C, 20D, 20E, and 20F. The plurality of connection components 30 include two connection components 30A and 30B. The plurality of coupling bus bars 75 include two coupling bus bars 75A and 75B. The plurality of external coupling bus bars 76 include two external coupling bus bars 76A and 76B.

### First Routing Example

First, a routing example related to the bus bar 42A will be described. The bus bar 42A has the first connection portion 61, the second connection portion 62, and extending portion 63. The first connection portion 61 is located on the +X direction side with respect to the electronic component 10A when viewed from the Z direction. The first connection portion 61 is electrically connected to the terminal 13A of the electronic component 10A via the connection component 20A that is the first connection component 20. The second connection portion 62 is located on the −X direction side with respect to the electronic component 10A when viewed from the Z direction. The second connection portion 62 is electrically connected to another subunit SU via the coupling bus bar 75A.

The extending portion 63 is accommodated in the accommodation portion 55 to extend over both sides of the region R through the region R overlapping the electronic component 10A when viewed from the Z direction. For example, the extending portion 63 extends linearly in the X direction. The extending portion 63 extends over the region R overlapping the electronic component 10A when viewed from the Z direction, over the +X direction side and the −X direction side of the region R. The bus bar 42A is, for example, a bus bar included in the positive electrode line PL included in the electrical connection unit 1.

### Second Routing Example

Next, a routing example related to the bus bar 42B will be described. The bus bar 42B has the first connection portion 61, the second connection portion 62, the extending portion 63, and the extension 64. The first connection portion 61 is electrically connected to the terminal 13B of the electronic component 10A via the connection component 20B that is the first connection component 20. The second connection portion 62 is electrically connected to the external connection bus bar 76A via the connection component 30A that is the second connection component 30. The extension 64 extends to the region R overlapping the electronic component 10A when viewed from the Z direction, and has an end 42e1 of the bus bar 42 at a position overlapping the electronic component 10A. Similarly to the bus bar 42A, the bus bar 42B may have an extending portion 63 that extends through the region R overlapping the electronic component 10 and over both sides of the region R when viewed from the Z direction. The bus bar 42B is, for example, a bus bar included in the positive electrode line PL included in the electrical connection unit 1.

### Third Routing Example

Next, a routing example related to the bus bar 42C will be described. The bus bar 42C includes the first connection portion 61, the second connection portion 62, the extending portion 63, and the extension 64. The first connection portion 61 is electrically connected to the terminal 13B of the electronic component 10B via the connection component 20C that is the first connection component 20. The second connection portion 62 is electrically connected to another subunit SU via the coupling bus bar 75B. The extension 64 extends to the region R overlapping the electronic component 10B when viewed from the Z direction, and has an end 42e1 of the bus bar 42 at a position overlapping the electronic component 10B when viewed from the Z direction. The bus bar 42C is, for example, a bus bar included in the negative electrode line NL included in the electrical connection unit 1.

### Fourth Routing Example

Next, a routing example related to the bus bar 42D will be described. The bus bar 42D has the first connection portion 61, the second connection portion 62, and the extending portion 63. The first connection portion 61 is electrically connected to the terminal 13A of the electronic component 10B via the connection component 20D that is the first connection component 20. The second connection portion 62 is electrically connected to the terminal 13B of the electronic component 10C via the connection component 20E that is the second connection component 20. The bus bar 42D is, for example, a bus bar included in the negative electrode line NL included in the electrical connection unit 1.

### Fifth Routing Example

Next, a routing example related to the bus bar 42E will be described. The bus bar 42E has the first connection portion 61, the second connection portion 62, and the extending portion 63. The first connection portion 61 is electrically connected to the terminal 13A of the electronic component 10C via the connection component 20F that is the first connection component 20. The second connection portion 62 is electrically connected to the external connection bus bar 76B via the connection component 30B that is the second connection component 30. The bus bar 42E is, for example, a bus bar included in the negative electrode line NL included in the electrical connection unit 1.

### Fastening Member

Next, referring to FIG. 9 again, the fastening member 43 will be described. The fastening member 43 is a component for fixing the bus bar 42 and a connection target component (the connection component 20, the connection component 30, or the coupling bus bar 75) of the bus bar 42. The fastening member 43 is, for example, a caulking bolt fixed to the bus bar 42. The fastening member 43 is an example of a “fastening portion”.

In the present embodiment, each of the first connection portion 61 and the second connection portion 62 of the bus bar 42 has a through-hole 42h. The through-hole 42h penetrates the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 42h of the bus bar 42. With this fixation, the fastening member 43 is electrically and physically connected to the bus bar 42 in a state in which the shaft 43a protrudes in the +Z direction from the through-hole 42h of the bus bar 42. The fastening member 43 is not limited to caulking fixation, and may be fixed to the bus bar 42 through welding or other methods.

In the present embodiment, the connection component 20 is attached to the fastening member 43 from the Z direction in a state of being previously fixed to the electronic component 10 via the fastening member 72 or the fastening member 71. For example, in the connection component 20, the shaft 43a of the fastening member 43 is inserted into the attachment hole 22h of the second portion 22. The engagement member 44 (for example, a nut) is engaged with the shaft 43a of the fastening member 43 protruding from the attachment hole 22h of the second portion 22 of the connection component 20. The engagement member 44 is attached to the shaft 43a in the Z direction, for example. This engagement fixes the second portion 22 of the connection component 20 to the fastening member 43.

### 4. Metal Plate, Insulating Sheet, Heat Transfer Member, and Insulating Cover

Next, the metal plate 80, the insulating sheet 91, the heat transfer member 92, and the insulating cover 93 will be described.

### 4.1 Metal Plate

FIG. 11 is a partially exploded perspective view of the electrical connection unit 1. The metal plate 80 is a member for securing rigidity of the electrical connection unit 1 and enhancing a heat dissipation property of the electrical connection unit 1. The metal plate 80 is made of a metal (for example, aluminum or an aluminum alloy). The metal plate 80 is an example of a “heat dissipation member”. The metal plate 80 may be referred to as a “metal member”or a “rigid member”.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. The metal plate 80 includes, for example, a flat surface portion 81, a plurality of fixing portions 82, and a plurality of fixing portions 83.

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the three subunits SU from below. The flat surface portion 81 faces, for example, all the electronic components 10 and all the bus bars 42 included in the electrical connection unit 1. The flat surface portion 81 faces the routing boards 40 of the three subunits SU. In the present embodiment, the metal plate 80 forms a gap S1 (see FIG. 13) with the second surface 51b of the flat surface portion 51 of each subunit SU, and faces the second surface 51b of the flat surface portion 51 of each subunit SU.

The fixing portion 82 is a fixing portion for fixing the base plate 41 of each subunit SU to the metal plate 80. The fixing portion 82 is provided at a position corresponding to the fixing portion 52 of the base plate 41 of each subunit SU when viewed from the Z direction. The fixing portion 82 is a cylindrical or prismatic boss protruding in the +Z direction from the flat surface portion 81 of the metal plate 80. The fixing portion 82 will be described in detail later.

The fixing portion 83 is a fixing portion for directly fixing the electronic component 10 of each subunit SU to the metal plate 80 without interposing the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81. The fixing portion 83 will be described in detail later.

### 4.2 Insulating Sheet

The insulating sheet 91 is an insulating member for electrically insulating the metal plate 80 and the bus bar 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 has a sheet shape formed in the horizontal direction. The insulating sheet 91 is disposed between the flat surface portion 81 of the metal plate 80 and the routing board 40 of each subunit SU. For example, the insulating sheet 91 is disposed between the flat surface portion 81 of the metal plate 80 and the plurality of heat transfer members 92.

In the present embodiment, the insulating sheet 91 is attached to the flat surface portion 81 of the metal plate 80. The insulating sheet 91 has a notch or an opening for avoiding the fixing portion 82 and the fixing portion 83 of the metal plate 80. Note that, instead of the above example, the insulating sheet 91 may be provided between the routing board 40 of each subunit SU and the plurality of heat transfer members 92. Note that, in a case where the heat transfer member 92 has an insulating property and the necessary insulating property is secured by the heat transfer member 92, the insulating sheet 91 may be omitted.

### 4.3 Heat Transfer Member

The heat transfer member 92 is a member for transferring heat generated by the electronic component 10 at the time of energization and/or heat (Joule heat) generated by the bus bar 42 itself at the time of energization to the metal plate 80. The heat transfer member 92 is, for example, a heat transfer sheet (for example, a thermally conductive silicone sheet) having elasticity. The heat transfer member 92 is made of a material having higher thermal conductivity than that of the base plate 41, for example. However, the heat transfer member 92 is not limited to the above example, and may be a heat transfer member made of a thermally conductive gel or another material.

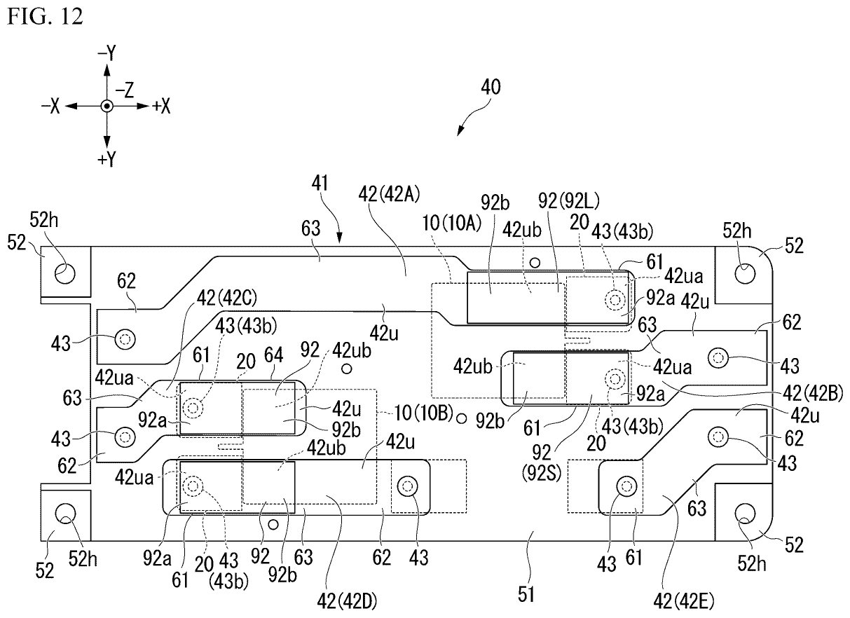

FIG. 12 is a bottom view illustrating the routing board 40. In the present embodiment, the plurality of heat transfer members 92 are partially provided in the routing board 40. For example, the plurality of heat transfer members 92 are disposed at positions overlapping a part of the bus bar 42 when viewed from the Z direction. More specifically, the plurality of heat transfer members 92 are disposed at positions overlapping a part of the bus bar 42 in the vicinity of the electronic component 10 (for example, the electronic components 10A and 10B) when viewed from the Z direction. In the present embodiment, the plurality of heat transfer members 92 are disposed at positions overlapping the connection component 20 when viewed from the Z direction. Note that a disposition position of the heat transfer member 92 is not limited to the above-described example. For example, the heat transfer member 92 may be disposed at a position not overlapping the connection component 20 or may be disposed at a position not overlapping the electronic component 10 when viewed from the Z direction.

In the present embodiment, the plurality of heat transfer members 92 include a heat transfer member 92S and a heat transfer member 92L. The heat transfer member 92L is larger than the heat transfer member 92S. Hereinafter, when the heat transfer member 92S and the heat transfer member 92L are not distinguished from each other, they are simply referred to as “heat transfer member 92”.

FIG. 13 is a cross-sectional view taken along line F13-F13 of the structure illustrated in FIG. 10. In the present embodiment, the heat transfer member 92 is disposed between the metal plate 80 and the bus bar 42. The heat transfer member 92 transfers heat transferred from the electronic component 10 to the bus bar 42 and/or heat generated by the bus bar 42 from the bus bar 42 to the metal plate 80.

In the present embodiment, a part of the heat transfer member 92 is in contact with the bus bar 42 at a position overlapping the connection component 20 when viewed from the Z direction. In this case, the heat transfer member 92 easily transfers the heat transferred from the terminal 13 of the electronic component 10 to the connection component 20 from the connection component 20 to the metal plate 80 via the bus bar 42. Instead of/in addition to the above example, a part of the heat transfer member 92 may be in contact with the bus bar 42 at a position overlapping the connection component 30 when viewed from the Z direction. In this case, the heat transfer member 92 easily transfers the heat transferred from an external device to the connection component 30, from the connection component 30 to the metal plate 80 via the bus bar 42.

In the present embodiment, a part of the heat transfer member 92 is disposed at a position overlapping the head 43b of the fastening member 43 when viewed from the Z direction, and is in contact with the head 43b of the fastening member 43. In this case, the heat transfer member 92 easily transfers the heat transferred from the terminal 13 of the electronic component 10 to the connection component 20 from the fastening member 43 to the metal plate 80. When a part of the heat transfer member 92 is in contact with the head 43b of the fastening member 43, the heat transfer member 92 easily transfers the heat transferred from the external device to the connection component 30, from the fastening member 43 to the metal plate 80.

In the present embodiment, a part of the heat transfer member 92 is in contact with the bus bar 42 at a position overlapping the electronic component 10 when viewed from the Z direction. In this case, the heat transfer member 92 easily transfers the heat transferred from the electronic component 10 to the bus bar 42 from the bus bar 42 to the metal plate 80. In the example illustrated in FIG. 13, the upper surface of the bus bar 42 is in contact with the electronic component 10, and thus the bus bar 42 is thermally connected to the electronic component 10. Note that the bus bar 42 may be thermally connected to the electronic component 10 at the extending portion 63 or the extension 64.

### Modification Example

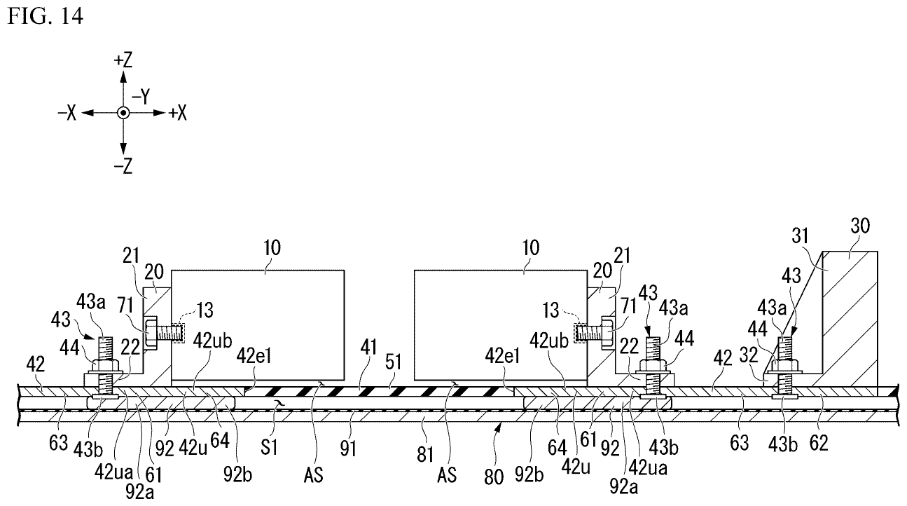

FIG. 14 is a cross-sectional view illustrating one modification example. In the present modification example, an air layer AS that is a gap exists between the bus bar 42 and the electronic component 10. The bus bar 42 is thermally connected to the electronic component 10 via the air layer AS. According to this constitution, the heat generated by the electronic component 10 is moved to the bus bar 42 through the air layer AS. The heat moved to the bus bar 42 is moved to the metal plate 80 via the heat transfer member 92 and dissipated.

### Modification Example

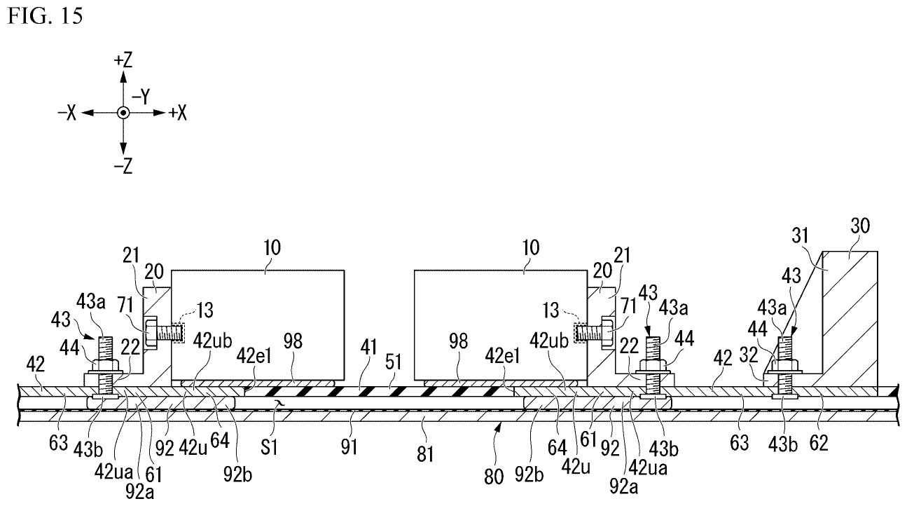

FIG. 15 is a cross-sectional view illustrating another modification example. In the present modification example, a heat transfer member 98 is provided between the bus bar 42 and the electronic component 10. The heat transfer member 98 is interposed between the bus bar 42 and the electronic component 10 in the Z direction. The bus bar 42 is thermally connected to the electronic component 10 via the heat transfer member 98. The heat transfer member 98 transfers heat generated by the electronic component 10 to the bus bar 42. The heat transfer member 98 is, for example, a heat transfer sheet (for example, a thermally conductive silicone sheet) having elasticity. However, the heat transfer member 98 is not limited to the above example, and may be a heat transfer member made of a thermally conductive gel or another material. According to this constitution, heat generated by the electronic component 10 is efficiently moved to the bus bar 42 via the heat transfer member 98. The heat moved to the bus bar 42 is moved to the metal plate 80 via the heat transfer member 92 and dissipated.

### 4.4 Insulating Cover

Referring to FIG. 1 again, the insulating cover 93 will be described. The insulating cover 93 is a member for preventing the main body MU from contacting the energization path. The insulating cover 93 is made of, for example, a synthetic resin and has an insulating property. The insulating cover 93 has, for example, a box shape that is open on the −Z direction side. The insulating cover 93 has a plurality of vent holes 93h. The insulating cover 93 is attached to the metal plate 80 in the Z direction. Note that the insulating cover 93 is not limited to a box-shaped member, and may be a sheet-shaped member that covers the energization path of the main body MU.

### 5. Exposure Structure of Bus Bar

Next, an exposure structure of the bus bar 42 will be described.

### 5.1 Exposure Structure on Upper Surface Side of Bus Bar

First, an exposure structure on the upper surface side of the bus bar 42 will be described with reference to FIG. 8. In the present embodiment, at least a part of the extending portion 63 of the bus bar 42 is exposed to the outside of the base plate 41 on the upper surface side (the first surface 51a side of the flat surface portion 51). For example, the extending portion 63 of the bus bar 42 is exposed to the outside of the base plate 41 on the upper surface side at least in a part of the region R (see FIG. 10) overlapping the electronic component 10 when viewed from the Z direction.

In the present embodiment, the bus bar 42 is accommodated in the accommodation portion 55 at least over the entire length between the first connection portion 61 and the second connection portion 62 and extends along the first surface 51a of the flat surface portion 51. The bus bar 42 is exposed to the outside of the base plate 41 on the upper surface side at least over the entire length between the first connection portion 61 and the second connection portion 62.

In the present embodiment, the bus bar 42 is accommodated in the accommodation portion 55 over the entire length of the bus bar 42 and extends along the first surface 51a of the flat surface portion 51. The bus bar 42 is exposed to the outside of the base plate 41 on the upper surface side over the entire length of the bus bar 42.

As illustrated in FIG. 13, at least a part of the extending portion 63 of the bus bar 42 is exposed to the outside of the base plate 41 not only on the upper surface side but also on the lower surface side (second surface 51b side). For example, the bus bar 42 is exposed to the outside of the base plate 41 on the lower surface side over the entire length of the bus bar 42.

### Modification Example

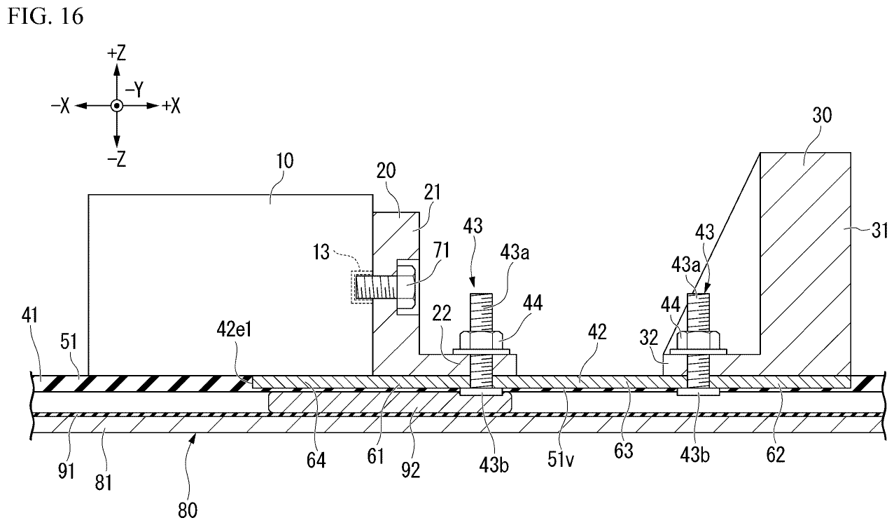

FIG. 16 is a cross-sectional view illustrating one modification example. In the present modification example, the flat surface portion 51 of the base plate 41 has a cover portion 51v that covers at least a part of the extending portion 63 of the bus bar 42 on the lower surface side (second surface 51b side). In the region covered by the cover portion 51v, the bus bar 42 is not exposed to the lower surface side. The cover portion 51v may be provided over the entire length of the bus bar 42. Note that the cover portion 51v need not be provided, for example, in a region overlapping the heat transfer member 92 when viewed from the Z direction.

### 5.2 Exposure Structure on Lower Surface Side of Bus Bar

Next, an exposure structure on the lower surface side of the bus bar 42 will be described with reference to FIG. 13. In the present embodiment, the plate portion 42p of the bus bar 42 includes an exposed portion 42u exposed to the outside of the base plate 41 on the lower surface side (the second surface 51b side of the flat surface portion 51). In the present embodiment, the exposed portion 42u of the bus bar 42 extends over the entire length of the bus bar 42. In the present embodiment, the heat transfer member 92 is disposed between the exposed portion 42u of the bus bar 42 and the metal plate 80. For example, the heat transfer member 92 is in contact with the exposed portion 42u of the bus bar 42.

In the present embodiment, at least a part of the exposed portion 42u of the bus bar 42 is provided in a region overlapping the connection component 20 when viewed from the Z direction. At least a part of the heat transfer member 92 overlaps the exposed portion 42u of the bus bar 42 in a region overlapping the connection component 20 when viewed from the Z direction. For example, at least a part of the heat transfer member 92 is in contact with the exposed portion 42u of the bus bar 42 in a region overlapping the connection component 20 when viewed from the Z direction.

In the present embodiment, the exposed portion 42u of the bus bar 42 includes a first portion 42ua disposed in a region overlapping the connection component 20 when viewed from the Z direction and a second portion 42ub disposed in a region overlapping the electronic component 10 when viewed from the Z direction.

The heat transfer member 92 includes a first heat transfer portion 92a and a second heat transfer portion 92b. The first heat transfer portion 92a overlaps the first portion 42ua of the exposed portion 42u of the bus bar 42 in a region overlapping the connection component 20 when viewed from the Z direction. For example, the first heat transfer portion 92a is in contact with the first portion 42ua of the exposed portion 42u of the bus bar 42. On the other hand, the second heat transfer portion 92b overlaps the second portion 42ub of the exposed portion 42u of the bus bar 42 in a region overlapping the electronic component 10 when viewed from the Z direction. For example, the second heat transfer portion 92b is in contact with the second portion 42ub of the exposed portion 42u of the bus bar 42.

As described above, at least a part of the extending portion 63 of the bus bar 42 is exposed to the outside of the base plate 41 not only on the lower surface side but also on the upper surface side (first surface 51a side). For example, the bus bar 42 is exposed to the outside of the base plate 41 on the upper surface side over the entire length of the bus bar 42. For example, the second portion 42ub of the exposed portion 42u of the bus bar 42 is exposed to the outside of the base plate 41 not only on the lower surface side but also on the upper surface side, and faces the electronic component 10.

### Modification Example

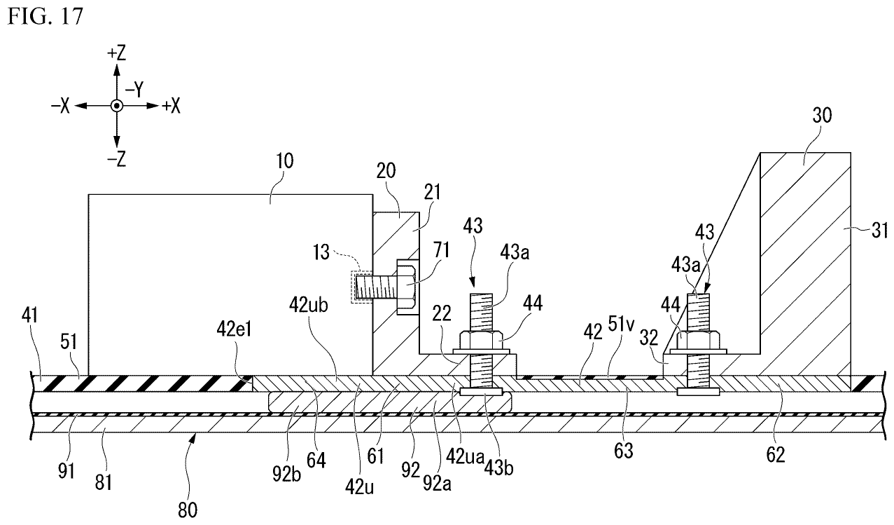

FIG. 17 is a cross-sectional view illustrating one modification example. In the present modification example, the flat surface portion 51 of the base plate 41 has a cover portion 51v that covers at least a part of the extending portion 63 of the bus bar 42 on the upper surface side (first surface 51a side). In the region covered by the cover portion 51v, the bus bar 42 is not exposed to the upper surface side. Note that the cover portion 51v may be provided over the entire length of the bus bar 42. Note that the cover portion 51v need not be provided, for example, in a region overlapping the first connection portion 61 and the second connection portion 62 when viewed from the Z direction.

### 6. Size and Disposition of Heat Transfer Member

### 6.1 Disposition Example of the electronic component

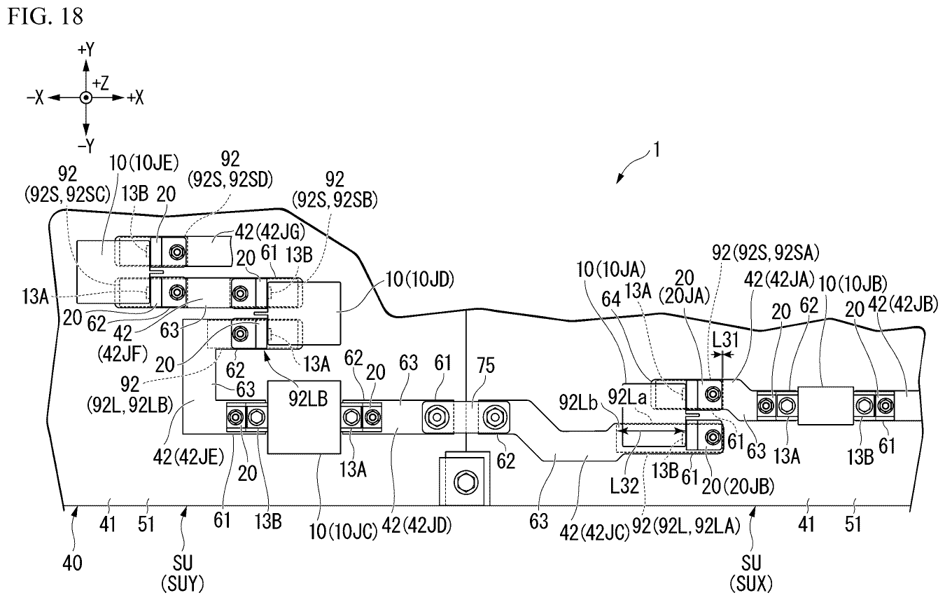

FIG. 18 is a plan view for describing a size and a disposition of the heat transfer member 92. In the present embodiment, the electrical connection unit 1 includes, as the electronic components 10 described above, an electronic component 10JA, an electronic component 10JB, an electronic component 10JC, an electronic component 10JD, and an electronic component 10JE. Each of the electronic components 10JA, 10JB, 10JC, 10JD, and 10JE may be the above-described first-type electronic component 10M or the above-described second-type electronic component 10N. In the example illustrated in FIG. 18, the electronic components 10JA, 10JB, 10JC, 10JD, and 10JE are separately disposed in a plurality of subunits SU. For example, the electronic component 10JA and the electronic component 10JB are provided in the subunit SUX. On the other hand, the electronic component 10JC, the electronic component 10JD, and the electronic component 10JE are provided in the subunit SUY.

In the present embodiment, the electronic component 10JC has a greater amount of heat generation during energization (during operation of the electrical connection unit 1) than the electronic component 10JA, the electronic component 10JB, the electronic component 10JD, and the electronic component 10JE. The electronic components 10JA, 10JB, 10JD, and 10JE are, for example, connectors, fuses, relays (for example, a mechanical relay or a semiconductor relay), capacitors, branch components, various sensors (for example, voltage sensors), electronic control units, or electronic component units obtained by unitizing two or more of these. On the other hand, the electronic component 10JC is a pyrofuse or a current sensor (for example, a current sensor having a shunt resistor). However, the types of the electronic components 10JA, 10JB, 10JC, 10JD, and 10JE are not limited to the examples described above. The electronic component 10JA is an example of a “first electronic component”. The electronic component 10JB is an example of each of a “second electronic component” and a “connection target component”. The electronic component 10JC is an example of a “third electronic component”.

### 6.2 Disposition Example of the Bus Bar

In the present embodiment, the electrical connection unit 1 includes, as the above-described bus bars 42, a bus bar 42JA, a bus bar 42JB, a bus bar 42JC, a bus bar 42JD, a bus bar 42JE, a bus bar 42JF, and a bus bar 42JG. The bus bars 42JA, 42JB, 42JC, 42JD, 42JE, 42JF, and 42JG are disposed to be arranged in the horizontal direction at intervals. The bus bars 42JA, 42JB, 42JC, 42JD, 42JE, 42JF, and 42JG include portions disposed on the same plane. The bus bars 42JA, 42JB, 42JC, 42JD, 42JE, 42JF, and 42JG are held by the flat surface portion 51 of the base plate 41.

At least a part of each of the bus bars 42JA, 42JB, 42JC, 42JD, 42JE, 42JF, and 42JG has a plate shape formed in the horizontal direction. At least a part of each of the bus bars 42JA, 42JB, 42JC, 42JD, 42JE, 42JF, and 42JG is accommodated in the accommodation portion 55 and extends along the flat surface portion 51. That is, at least a part of each of the bus bars 42JA, 42JB, 42JC, 42JD, 42JE, 42JF, and 42JG extends along the first surface 51a of the flat surface portion 51. At least a part of each of the bus bars 42JA, 42JB, 42JC, 42JD, 42JE, 42JF, and 42JG extends in the horizontal direction in the accommodation portion 55. In the present embodiment, each of the bus bars 42JA, 42JB, 42JC, 42JD, 42JE, 42JF, and 42JG has a plate shape formed in the horizontal direction over the entire bus bar 42. Each of the bus bars 42JA, 42JB, 42JC, 42JD, 42JE, 42JF, and 42JG is accommodated in the accommodation portion 55 over the entire length of the bus bar 42 and extends along the flat surface portion 51. These bus bars 42JA, 42JB, 42JC, 42JD, 42JE, 42JF, and 42JG face the metal plate 80 in the Z direction.

### Bus Bar 42JA

The bus bar 42JA electrically connects the terminal 13A of the electronic component 10JA to the terminal 13A of the electronic component 10JB. In the present embodiment, the first connection portion 61 of the bus bar 42JA is located on the +X direction side with respect to the electronic component 10JA when viewed from the Z direction. The first connection portion 61 of the bus bar 42JA is electrically connected to the terminal 13A of the electronic component 10JA via the connection component 20 (connection component 20JA). The second connection portion 62 of the bus bar 42JA is electrically connected to the terminal 13A of the electronic component 10JB via another connection component 20. The terminal 13A of the electronic component 10JA is an example of a “first terminal”. The bus bar 42JA is an example of a “first bus bar”. The connection component 20JA is an example of a “first connection component”.

### Bus Bar 42JB

The bus bar 42JB electrically connects the terminal 13B of the electronic component 10JB to another electronic component 10 or the connection component 30. For example, the first connection portion 61 of the bus bar 42JB is electrically connected to the terminal 13B of the electronic component 10JB via the connection component 20. The second connection portion 62 of the bus bar 42JB is electrically connected to another electronic component 10 or the connection component 30.

### Bus Bar 42JC

The bus bar 42JC electrically connects the terminal 13B of the electronic component 10JA to the terminal 13A of the electronic component 10JC. In the present embodiment, the first connection portion 61 of the bus bar 42JC is located on the +X direction side with respect to the electronic component 10JA when viewed from the Z direction. The first connection portion 61 of the bus bar 42JC is electrically connected to the terminal 13B of the electronic component 10JA via the connection component 20 (connection component 20JB). The second connection portion 62 of the bus bar 42JC is located on the −X direction side with respect to the electronic component 10JA when viewed from the Z direction. The second connection portion 62 of the bus bar 42JC is electrically connected to the coupling bus bar 75, and is electrically connected to the terminal 13A of the electronic component 10JC via the coupling bus bar 75 and the bus bar 42JD. The terminal 13B of the electronic component 10JA is an example of a “second terminal”. The bus bar 42JC is an example of a “second bus bar”. The connection component 20JB is an example of a “second connection component”.

### Bus Bar 42JD

The bus bar 42JD electrically connects the bus bar 42JC to the terminal 13A of the electronic component 10JC. In the present embodiment, the first connection portion 61 of the bus bar 42JD is electrically connected to the coupling bus bar 75. The second connection portion 62 of the bus bar 42JD is electrically connected to the terminal 13A of the electronic component 10JC via the connection component 20.

### Bus Bar 42JE

The bus bar 42JE electrically connects the terminal 13B of the electronic component 10JC to the terminal 13A of the electronic component 10JD. In the present embodiment, the first connection portion 61 of the bus bar 42JE is electrically connected to the terminal 13B of the electronic component 10JC via the connection component 20. The second connection portion 62 of the bus bar 42JE is electrically connected to the terminal 13A of the electronic component 10JD via the connection component 20.

### Bus Bar 42JF

The bus bar 42JF electrically connects the terminal 13B of the electronic component 10JD to the terminal 13A of the electronic component 10JE. In the present embodiment, the first connection portion 61 of the bus bar 42JF is electrically connected to the terminal 13B of the electronic component 10JD via the connection component 20. The second connection portion 62 of the bus bar 42JF is electrically connected to the terminal 13A of the electronic component 10JE via the connection component 20.

### Bus Bar 42JG

The bus bar 42JG electrically connects the terminal 13B of the electronic component 10JD and another electronic component 10. In the present embodiment, the first connection portion 61 of the bus bar 42JG is electrically connected to the terminal 13B of the electronic component 10JD via the connection component 20. On the other hand, the second connection portion 62 of the bus bar 42JF is electrically connected to another electronic component 10 via the connection component 20.

### 6.3 Disposition Example of Heat Transfer Member

In the present embodiment, the electrical connection unit 1 includes a plurality of heat transfer members 92S (heat transfer members 92SA, 92SB, 92SC, and 92SD) and a plurality of heat transfer members 92L (heat transfer members 92LA and 92LB) as the heat transfer members 92 described above.

### Heat Transfer Member 92SA

The heat transfer member 92SA is disposed between the bus bar 42JA and the flat surface portion 81 of the metal plate 80, and transfers heat from the bus bar 42JA to the metal plate 80. For example, a part of the heat transfer member 92SA overlaps the electronic component 10JA when viewed from the Z direction. Another part of heat transfer member 92SA overlaps the connection component 20JA connecting the electronic component 10JA to the bus bar 42JA when viewed from the Z direction. The heat transfer member 92SA is an example of a “first heat transfer member”.

### Heat Transfer Member 92LA

The heat transfer member 92LA is disposed between the bus bar 42JC and the flat surface portion 81 of the metal plate 80, and transfers heat from the bus bar 42JC to the metal plate 80. For example, a part of the heat transfer member 92LA overlaps the electronic component 10JA when viewed from the Z direction. Another part of the heat transfer member 92LA overlaps the connection component 20JB connecting the electronic component 10JA to the bus bar 42JC when viewed from the Z direction. The heat transfer member 92LA is an example of a “second heat transfer member”.

### Heat Transfer Member 92LB

The heat transfer member 92 LB is disposed between the bus bar 42JE and the flat surface portion 81 of the metal plate 80, and transfers heat from the bus bar 42JE to the metal plate 80. For example, a part of the heat transfer member 92 LB overlaps the electronic component 10JD when viewed from the Z direction. Another part of the heat transfer member 92 LB overlaps the connection component 20 connecting the electronic component 10JD to the bus bar 42JE when viewed from the Z direction.

### Heat Transfer Member 92SB

The heat transfer member 92SB is disposed between the bus bar 42JF and the flat surface portion 81 of the metal plate 80, and transfers heat from the bus bar 42JF to the metal plate 80. For example, a part of the heat transfer member 92SB overlaps the electronic component 10JD when viewed from the Z direction. Another part of the heat transfer member 92SB overlaps the connection component 20 connecting the electronic component 10JD to the bus bar 42JF when viewed from the Z direction.

### Heat Transfer Member 92SC

The heat transfer member 92SC is disposed between the bus bar 42JF and the flat surface portion 81 of the metal plate 80, and transfers heat from the bus bar 42JF to the metal plate 80. For example, a part of the heat transfer member 92SC overlaps the electronic component 10JE when viewed from the Z direction. Another part of the heat transfer member 92SB overlaps the connection component 20 connecting the electronic component 10JE to the bus bar 42JF when viewed from the Z direction.

### Heat Transfer Member 92SD

The heat transfer member 92SD is disposed between the bus bar 42JG and the flat surface portion 81 of the metal plate 80, and transfers heat from the bus bar 42JG to the metal plate 80. For example, a part of the heat transfer member 92SD overlaps the electronic component 10JE when viewed from the Z direction. Another part of the heat transfer member 92SD overlaps the connection component 20 connecting the electronic component 10JE to the bus bar 42JG when viewed from the Z direction.

### 6.3 Size of Heat Transfer Member

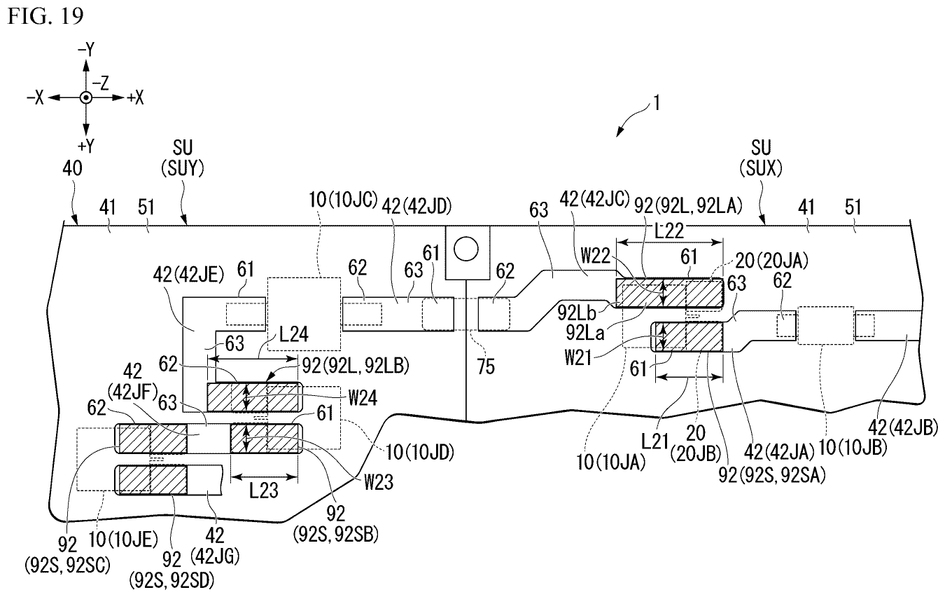

FIG. 19 is a bottom view for describing a size and a disposition of the heat transfer member 92. In FIG. 19, hatching is applied to the heat transfer member 92 for convenience of description. In the present embodiment, the heat transfer member 92L is larger than the heat transfer member 92S. For example, the heat transfer member 92L has a larger area than the heat transfer member 92S when viewed from the Z direction.

### Dimensional Relationship Between Heat Transfer Member 92LA and Heat Transfer Member 92SA

In the present embodiment, the heat transfer member 92LA is larger than the heat transfer member 92SA. For example, the heat transfer member 92LA has a larger area than the heat transfer member 92SA when viewed from the Z direction. For example, the longitudinal direction of the heat transfer member 92SA coincides with the extending direction (for example, the X direction) of the bus bar 42JA. The heat transfer member 92SA is disposed along the bus bar 42JA, and has a first length L21 in the extending direction (for example, the X direction) of the bus bar 42JA. On the other hand, the longitudinal direction of the heat transfer member 92LA coincides with the extending direction (for example, the X direction) of the bus bar 42JC. The heat transfer member 92LA is disposed along the bus bar 42JC, and has a second length L22 in the extending direction (for example, the X direction) of the bus bar 42JC. The second length L22 is larger than the first length L21. On the other hand, a width W22 of the heat transfer member 92LA in the Y direction is, for example, the same as a width W21 of the heat transfer member 92SA in the Y direction.

In the present embodiment, the heat transfer member 92LA protrudes from the connection component 20JB toward the electronic component 10JC side by a protrusion amount L32 (see FIG. 18). On the other hand, the heat transfer member 92SA does not protrude toward the electronic component 10JB side with respect to the connection component 20JA, or protrudes by a protrusion amount L31 smaller than the protrusion amount L32 (see FIG. 18). The protrusion amount L31 is an example of a “first protrusion amount”. The protrusion amount L32 is an example of a “second protrusion amount”.

In the present embodiment, the bus bar 42JC extends from the connection component 20JB toward the electronic component 10JC through between the electronic component 10JA and the metal plate 80. For example, the heat transfer member 92LA includes a portion extending toward the +X direction side from the end of the electronic component 10A on the +X direction side and a portion extending toward the −X direction side from the end of the electronic component 10A on the −X direction side. On the other hand, the heat transfer member 92SA has a portion extending toward the +X direction side from the end of the electronic component 10A on the +X direction side, but does not have a portion extending toward the −X direction side from the end of the electronic component 10A on the −X direction side.

In the present embodiment, the heat transfer member 92LA includes a first portion 92LAa and a second portion 92LAb. The first portion 92LAa overlaps the electronic component 10JA when viewed from the Z direction. The second portion 92LAb extends from the first portion 92LAa toward the electronic component 10JC. Second portion 92LAb does not overlap electronic component 10JA when viewed from the Z direction.

### Dimensional Relationship Between Heat Transfer Member 92LB and Heat Transfer Member 92SB

In the present embodiment, the heat transfer member 92 LB is larger than the heat transfer member 92SB. For example, the heat transfer member 92 LB has a larger area than the heat transfer member 92SB when viewed from the Z direction. For example, the heat transfer member 92SB is disposed along the bus bar 42JF, and has a third length L23 in the extending direction (for example, the X direction) of the bus bar 42JF. The heat transfer member 92 LB is disposed along the bus bar 42JE and has a fourth length L24 in the extending direction (for example, the X direction) of the bus bar 42JE. The fourth length L24 is larger than the third length L23. On the other hand, a width W24 of the heat transfer member 92 LB in the Y direction is, for example, the same as a width W23 of the heat transfer member 92SB in the Y direction.

The example in which the connection target component is the electronic component 10JB (second electronic component) has been described above. However, the connection target component may be the connection component 30 for external connection instead of the electronic component 10JB. For example, in the example illustrated in FIG. 12, the electronic component 10A is an example of a “first electronic component”. The bus bar 42B is an example of a “first bus bar”. The connection component 30A for external connection (see FIG. 10) is an example of a “connection target component”. The bus bar 42A is an example of a “second bus bar”. The second connection portion 62 of the bus bar 42A is electrically connected to the electronic component 10 having a greater amount of heat generation than the electronic component 10A. The electronic component 10 electrically connected to the second connection portion 62 of the bus bar 42A is an example of a “third electronic component”.

### 7. Fixing Structure

Next, a fixing structure of the subunit SU will be described.

### 7.1 Structure of Metal Plate

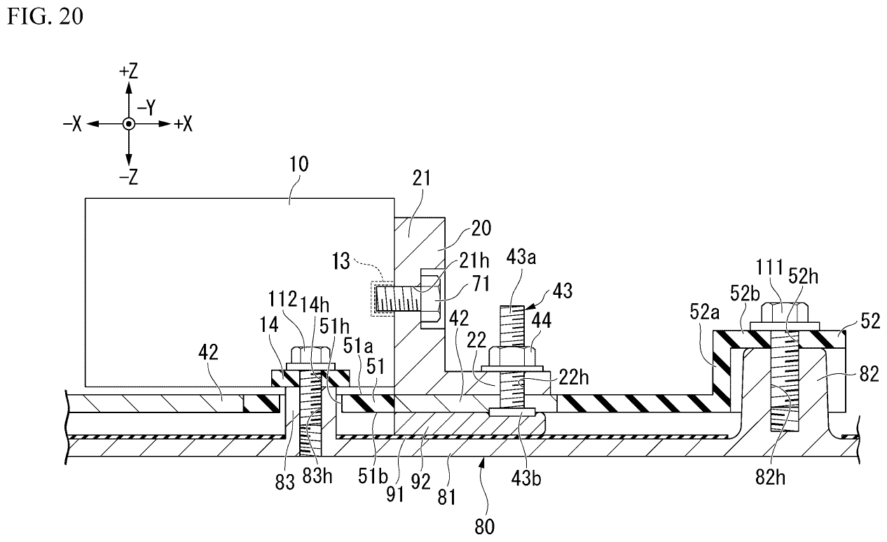

FIG. 20 is a cross-sectional view taken along line F20-F20 of the structure illustrated in FIG. 10. As described above, the metal plate 80 includes the fixing portion 82 and the fixing portion 83.

The fixing portion 82 is a boss protruding in the +Z direction from the flat surface portion 81 of the metal plate 80. For example, the fixing portion 82 protrudes to the +Z direction side from the first surface 51a of the flat surface portion 51 of the base plate 41. In the present embodiment, the fixing portion 82 protrudes more in the +Z direction than the fixing portion 83 that will be described later. The fixing portion 82 faces the fixing portion 52 of the base plate 41 in the Z direction. The fixing portion 82 has an engagement hole 82h that is open in the +Z direction. An inner circumferential surface of the engagement hole 82h has a screw groove.

The fixing portion 83 is a boss protruding in the +Z direction from the flat surface portion 81. The fixing portion 83 is inserted into a through-hole 51h (that will be described later) of the flat surface portion 51 of the base plate 41. For example, the fixing portion 83 passes through the through-hole 51h of the flat surface portion 51 and protrudes to the same position as the first surface 51a of the flat surface portion 51 or protrudes beyond a position of the first surface 51a of the flat surface portion 51 (a position on the +Z direction side with respect to the first surface 51a). The fixing portion 83 faces the attachment portion 14 of the electronic component 10 in the Z direction. The fixing portion 83 has an engagement hole 83h that is open in the +Z direction. An inner circumferential surface of the engagement hole 83h has a screw groove.

A fastening member 112 (for example, a screw or a bolt) passes through the attachment hole 14h of the attachment portion 14 of the electronic component 10 from the +Z direction side. When the fastening member 112 that has passed through the attachment hole 14h of the attachment portion 14 of the electronic component 10 is engaged with the engagement hole 83h of the fixing portion 83 of the metal plate 80, the electronic component 10 is fixed to the metal plate 80 without interposing the base plate 41.

### 7.2 Structure of Routing Board

The base plate 41 has the fixing portion 52 fixed to the fixing portion 82 of the metal plate 80. The fixing portion 52 includes, for example, a standing plate portion 52a and a horizontal plate portion 52b.

The standing plate portion 52a stands in the +Z direction from the end of the flat surface portion 51 of the base plate 41. The standing plate portion 52a is a plate portion provided in the Y direction and the Z direction. The thickness direction of the standing plate portion 52a is the X direction.

The horizontal plate portion 52b extends in the horizontal direction from the end of the standing plate portion 52a in the +Z direction. The horizontal plate portion 52b is a plate portion provided in the horizontal direction. The horizontal plate portion 52b faces the fixing portion 82 of the metal plate 80 in the Z direction. The horizontal plate portion 52b has an insertion hole 52h facing the engagement hole 82h of the fixing portion 82 of the metal plate 80. A fastening member 111 (for example, a screw or a bolt) passes through the insertion hole 52h. When the fastening member 111 that has passed through the insertion hole 52h of the fixing portion 52 of the base plate 41 is engaged with the engagement hole 82h of the fixing portion 82 of the metal plate 80, the base plate 41 is fixed to the metal plate 80.

The flat surface portion 51 of the base plate 41 has the above-described through-hole 51h. The through-hole 51h penetrates the flat surface portion 51 in the Z direction. The through-hole 51h is provided at a position corresponding to the fixing portion 83 of the metal plate 80 when viewed from the Z direction. The fixing portion 83 of the metal plate 80 passes through the through-hole 51h of the base plate 41 and protrudes to the same position as the first surface 51a of the flat surface portion 51 or to the +Z direction side with respect to the first surface 51a of the flat surface portion 51. The attachment portion 14 of the electronic component 10 is fixed to the fixing portion 83 at the same position as the first surface 51a of the flat surface portion 51 or at a position on the +Z direction side with respect to the first surface 51a of the flat surface portion 51.

### 8. Advantages

As a comparative example, a constitution in which all the heat transfer members 92 have the same size will be considered. In the constitution of this comparative example, since the size of the heat transfer member 92 is the same between a portion having large thermal interference and a portion having small thermal interference, there may be room for improvement in heat dissipation. For example, in the first electronic component, heat may move from the connection target component via the first bus bar, and heat may move from the third electronic component via the second bus bar. In this case, when the third electronic component has a greater amount of heat generation than the connection target component, a large amount of heat moves from the third electronic component to the first electronic component via the second bus bar (thermal interference increases). When a large amount of heat is transferred from the third electronic component to the first electronic component, it may be difficult to improve the heat dissipation property of the electrical connection unit 1.

Therefore, in the present embodiment, the electrical connection unit 1 includes a first electronic component (for example, the electronic component 10JA or the electronic component 10A), a connection target component that is a second electronic component (for example, the electronic component 10JB) or a connection component for external connection (for example, the connection component 30A), a third electronic component (for example, the electronic component 10JC or another electronic component 10), a first bus bar (for example, the bus bar 42JA or the bus bar 42B), a second bus bar (for example, the bus bar 42JC or the bus bar 42A), a heat dissipation member (for example, the metal plate 80), a first heat transfer member (for example, the heat transfer member 92S), and a second heat transfer member (for example, the heat transfer member 92L). The third electronic component has a greater amount of heat generation than the connection target component. The first bus bar electrically connects the first terminal of the first electronic component to the connection target component. The second bus bar electrically connects a second terminal of the first electronic component to the third electronic component. The heat dissipation member faces the first bus bar and the second bus bar. The first heat transfer member is disposed between the first bus bar and the heat dissipation member. The second heat transfer member is disposed between the second bus bar and the heat dissipation member, and is larger than the first heat transfer member.

According to such a constitution, even in a case where the third electronic component has a greater amount of heat generation than the connection target component, part of the heat moving from the third electronic component toward the first electronic component via the second bus bar can be caused to move toward the heat dissipation member by the second heat transfer member. Such heat movement can prevent a large amount of heat from being transferred from the third electronic component to the first electronic component via the second bus bar (increase in thermal interference). As a result, it is possible to balance the heat dissipation between the portion where the thermal interference is large and the portion where the thermal interference is small, and it is possible to improve the heat dissipation property of the electrical connection unit 1.

In the present embodiment, the second heat transfer member has a larger area than the first heat transfer member when viewed from the Z direction. According to such a constitution, part of heat moving from the third electronic component toward the first electronic component via the second bus bar can be caused to more effectively move toward the heat dissipation member by the second heat transfer member. Thus, the heat dissipation property of the electrical connection unit 1 can be further improved.

In the present embodiment, the connection target component is, for example, a second electronic component. The third electronic component has a greater amount of heat generation than the second electronic component. According to such a constitution, the movement of heat from the plurality of the electronic components (the second electronic component and the third electronic component) toward the first electronic component can be balanced in heat dissipation according to the magnitude of thermal interference. Thus, the heat dissipation property of the electrical connection unit 1 can be further improved.

In the present embodiment, the first heat transfer member is disposed along the first bus bar and has the first length L31 in the extending direction of the first bus bar. The second heat transfer member is disposed along the second bus bar and has the second length L32 in the extending direction of the second bus bar. The second length L32 is larger than the first length L31. According to such a constitution, since the first heat transfer member is disposed along the first bus bar and the second heat transfer member is disposed along the second bus bar, the heat dissipation property from the first bus bar and the second bus bar to the heat dissipation member can be enhanced. When the second length L32 is larger than the first length L31 while such a structure is realized, part of heat moving from the third electronic component toward the first electronic component via the second bus bar can be caused to more effectively move toward the heat dissipation member by the second heat transfer member. Thus, the heat dissipation property of the electrical connection unit 1 can be further improved.

In the present embodiment, the electrical connection unit 1 further includes a first connection component that connects the first terminal of the first electronic component to the first bus bar, and a second connection component that connects the second terminal of the first electronic component to the second bus bar. The second heat transfer member protrudes toward the third electronic component side by the protrusion amount L32 with respect to the second connection component. The first heat transfer member does not protrude toward the second electronic component side with respect to the first connection component, or protrudes by the protrusion amount L31 smaller than the protrusion amount L32. According to such a constitution, part of heat moving from the third electronic component toward the first electronic component via the second bus bar is caused to easily move toward the heat dissipation member at the position (a position on the third electronic component side) before the first electronic component. Thus, the heat dissipation property of the electrical connection unit 1 can be further improved.

In the present embodiment, the second bus bar extends toward the third electronic component through between the first electronic component and the heat dissipation member. The second heat transfer member includes the first portion 92La overlapping the first electronic component, and the second portion 92Lb extending from the first portion 92La toward the third electronic component. According to such a constitution, part of heat moving from the third electronic component toward the first electronic component via the second bus bar can be caused to easily move toward the heat dissipation member effectively at the earliest stage. Thus, the heat dissipation property of the electrical connection unit 1 can be further improved.

### 9. Modification Examples

Next, several modification examples will be described. Note that a constitution other than that described below in each modification example is the same as the constitution of the first embodiment.

### First Modification Example

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

### Second Modification Example

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by a part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### Third Modification Example

The base plate 41 of the routing board 40 may include a plurality of members (plate members or sheet members). The plurality of members are provided to sandwich the plurality of bus bars 42 arranged in the horizontal direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed.

### Fourth Modification Example

A connection between the electronic component 10 and the bus bar 42 is not limited to the connection using the connection component 20. The electronic component 10 may be directly connected to the bus bar 42 by using a fastening member (for example, a bolt or a screw), welding, or the like.

### SECOND EMBODIMENT

Next, a second embodiment will be described. The second embodiment is different from the first embodiment in that a holding portion 131 that supports the bus bar 42 that is in contact with the heat transfer member 92L is provided. The constitution other than that described below is the same as that of the first embodiment.

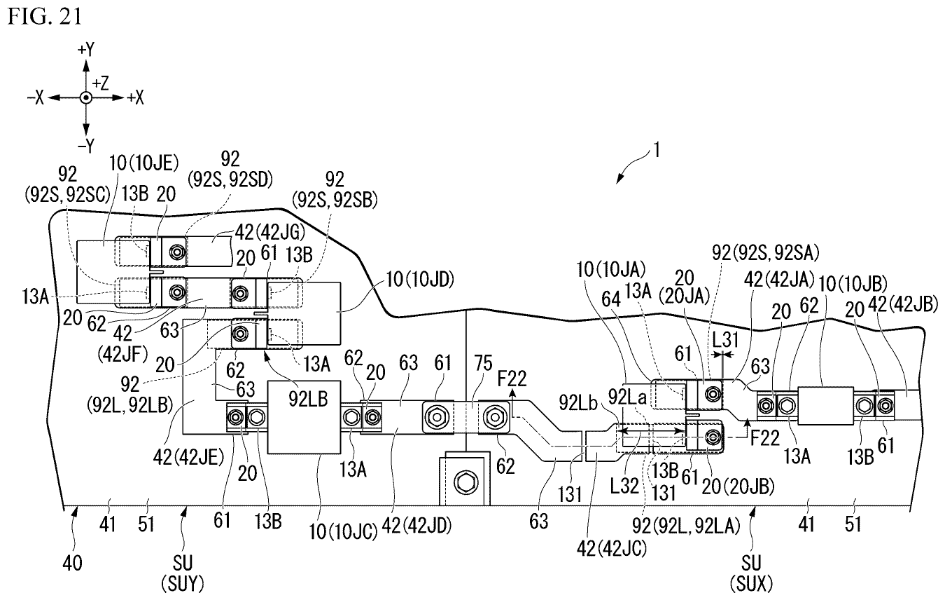

FIG. 21 is a plan view for describing an electrical connection unit 1 of the second embodiment. In the second embodiment, the base plate 41 includes a holding portion 131. The holding portion 131 overlaps a part of the bus bar 42 in contact with the heat transfer member 92L from the +Z direction side when viewed from the Z direction, and supports the bus bar 42 in the Z direction.

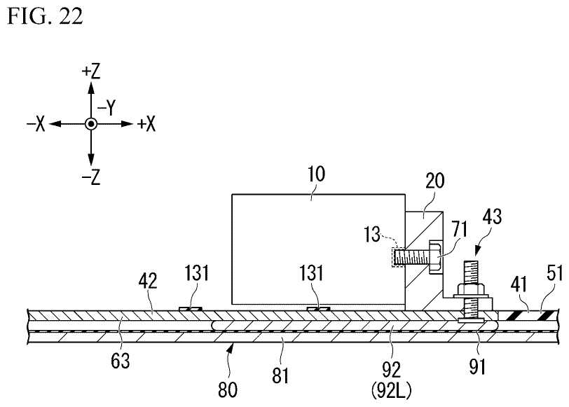

FIG. 22 is a cross-sectional view taken along line F22-F22 of the electrical connection unit 1 illustrated in FIG. 21. For example, the holding portion 131 is disposed adjacent to the first surface 51a of the flat surface portion 51, is disposed above the bus bar 42, and supports the bus bar 42 from above. The holding portion 131 holds the bus bar 42 so that, for example, the bus bar 42 does not fall off upward. Note that the holding portion 131 may be provided at a position overlapping the heat transfer member 92L or at a position deviating from the heat transfer member 92L when viewed from the Z direction.

According to such a constitution, even when a force in a direction of falling off upward acts on the bus bar 42 by a large elastic force of the heat transfer member 92L, the bus bar 42 is less likely to fall off from the base plate 41.

Note that the holding portion 131 may be formed through, for example, insert molding similarly to other portions of the flat surface portion 51. Alternatively, the holding portion 131 may be formed of a separate component attached to the base plate 41 after being provided separately from the base plate 41.

Several embodiments and modification examples have been described above. However, the embodiment and the modification examples are not limited to the examples described above. For example, a plurality of embodiments may be implemented in combination with each other.

### DESCRIPTION OF REFERENCE SYMBOLS

1 Electrical connection unit
SU Subunit
10 Electronic component
10A Electronic component (first electronic component)
10JA Electronic component (first electronic component)
10JB Electronic component (second electronic component and connection target component)
10JC Electronic component (third electronic component)
13, 13A, 13B Terminal
20 Connection component
20JA First connection component
20JB Second connection component
21 First portion
22 Second portion
30 Connection component (connection target component)
31 First portion
32 Second portion
40 Routing board
41 Base plate
42 Bus bar
42A Bus bar (second bus bar)
42B Bus bar (first bus bar)
42JA Bus bar (first bus bar)
42JC Bus bar (second bus bar)
55 Accommodation portion
80 Metal plate (heat dissipation member)
81 Flat surface portion
82 Fixing portion
83 Fixing portion
92 Heat transfer member
92S, 92SA Heat transfer member (first heat transfer member)
92L, 92LA Heat transfer member (second heat transfer member)
92La First portion
92Lb Second portion

1. An electrical connection unit comprising:
a first electronic component having a first terminal and a second terminal;
a connection target component that is a second electronic component or a connection component for external connection;
a third electronic component that has a greater amount of heat generation than the connection target component;
a first bus bar that electrically connects the first terminal of the first electronic component to the connection target component;
a second bus bar that electrically connects the second terminal of the first electronic component to the third electronic component;
a heat dissipation member that faces the first bus bar and the second bus bar;
a first heat transfer member that is disposed between the first bus bar and the heat dissipation member; and
a second heat transfer member that is disposed between the second bus bar and the heat dissipation member and is larger than the first heat transfer member.

2. The electrical connection unit according to claim 1, wherein
in a case where a direction from the first bus bar and the second bus bar toward the heat dissipation member is a first direction, the second heat transfer member has a larger area than the first heat transfer member when viewed from the first direction.

3. The electrical connection unit according to claim 1, wherein
the connection target component is the second electronic component, and
the third electronic component has a greater amount of heat generation than the second electronic component.

4. The electrical connection unit according to claim 1, wherein
the first heat transfer member is disposed along the first bus bar and has a first length in an extending direction of the first bus bar,
the second heat transfer member is disposed along the second bus bar and has a second length in an extending direction of the second bus bar, and
the second length is larger than the first length.

5. The electrical connection unit according to claim 1, further comprising:
a first connection component that connects the first terminal of the first electronic component to the first bus bar, and
a second connection component that connects the second terminal of the first electronic component to the second bus bar,
wherein
the second heat transfer member protrudes toward the third electronic component side with respect to the second connection component by a second protrusion amount, and
the first heat transfer member does not protrude toward the second electronic component side with respect to the first connection component, or protrudes by a first protrusion amount smaller than the second protrusion amount.

6. The electrical connection unit according to claim 1, wherein
the second bus bar extends toward the third electronic component through between the first electronic component and the heat dissipation member, and
in a case where a direction from the first bus bar and the second bus bar toward the heat dissipation member is a first direction, the second heat transfer member includes a first portion overlapping the first electronic component and a second portion extending from the first portion toward the third electronic component.
